(19) United States
(12) Patent Application Publication
(10) Pub. No.: US 2026/0030396 A1
(43) Pub. Date: Jan. 29, 2026

(54) SYSTEMS AND METHODS FOR COMPUTER-AIDED ROOF DESIGN

(71) Applicant: BMIC LLC, Dallas, TX (US)

(72) Inventors: James Willits, Fort Worth, TX (US); Mark Lienemann, Dallas, TX (US); David Scott, Grove City, OH (US); Walter Brown, Belvidere, IL (US); Leonel Alvarado, Montgomery, IL (US); Jay Smith, Dallas, TX (US)

(21) Appl. No.: 19/265,697

(22) Filed: Jul. 10, 2025

Related U.S. Application Data
(60) Provisional application No. 63/675,656, filed on Jul. 25, 2024.
(60) Provisional application No. 63/679,915, filed on Aug. 6, 2024.

(51) Int. Cl. G06F 30/13; G06F 30/27

(52) U.S. Cl. CPC G06F 30/13; G06F 30/27

(57) ABSTRACT

Systems and methods detailed herein include roof simulation and design, and roof construction based on such simulations and designs. To minimize material and part waste, as well as enable improved construction efficiency by augmenting computer-aided design tools with functionality to arrange roofing accessories for an optimal layout and to arrange staging of the roofing accessories in advance of or during construction for efficient construction, embodiments detailed herein improve computer-aided design tools for roof design, e.g., via a plug-in, extension, add-on or other modification, to enable the computer-aided design tools to create, from a computer-aided design drawing or other image of a roof, a roof layout, a staging layout and/or a bill-of-materials.

### FIELD OF TECHNOLOGY

The present disclosure generally relates to computer-based systems and methods for simulated roof layouts, including outputting staging and construction protocols.

### BACKGROUND OF TECHNOLOGY

Computer-aided design (“CAD”) software facilitates the creation, modification, analysis, or optimization of a design. Users of CAD software may be provided the functionality to create and/or select from parts or components to create a model of a larger part, component or system, including parameters such as dimensions, shapes, positioning and orientation. As a result the larger part, component or system may be built based on the model.

### BRIEF DESCRIPTION OF THE DRAWINGS

Various embodiments of the present disclosure can be further explained with reference to the attached drawings, wherein like structures are referred to by like numerals throughout the several views. The drawings shown are not necessarily to scale, with emphasis instead generally being placed upon illustrating the principles of the present disclosure. Therefore, specific structural and functional details disclosed herein are not to be interpreted as limiting, but merely as a representative basis for teaching one skilled in the art to variously employ one or more illustrative embodiments.

FIG. 1A is a block diagram of an exemplary computer-based system for roof design in accordance with one or more embodiments of the present disclosure.

FIG. 1B is a block diagram of an exemplary computer-based system for roof design in accordance with one or more embodiments of the present disclosure.

FIG. 2 illustrates a flowchart of an illustrative methodology in accordance with one or more embodiments of the present disclosure.

FIG. 3 depicts a block diagram of another exemplary computer-based system and platform for a roof design system in accordance with one or more embodiments of the present disclosure.

FIG. 4 depicts illustrative schematics of another exemplary implementation of the cloud computing/architecture(s) in which embodiments of a roof design system may be specifically configured to operate in accordance with some embodiments of the present disclosure.

FIG. 5 illustrates an example GUI incorporating the roof design system 100 for generating a roof design and/or layout of roofing components.

FIG. 6A, FIG. 6B, FIG. 6C, FIG. 6D, FIGS. 6E and 6F illustrate steps in a flow for generating an optimal staging plan for a roof design in accordance with one or more embodiments detailed herein.

### DETAILED DESCRIPTION

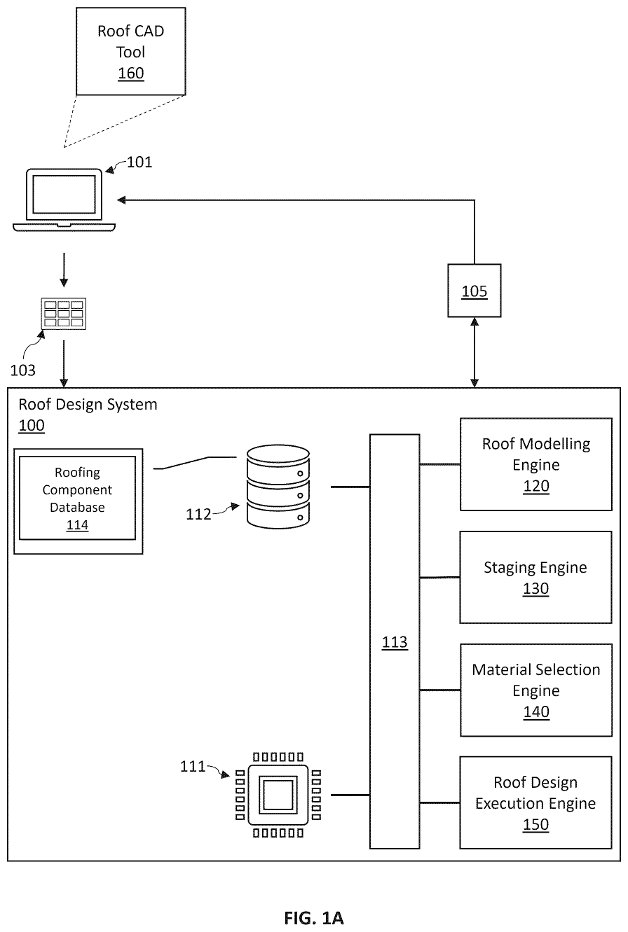

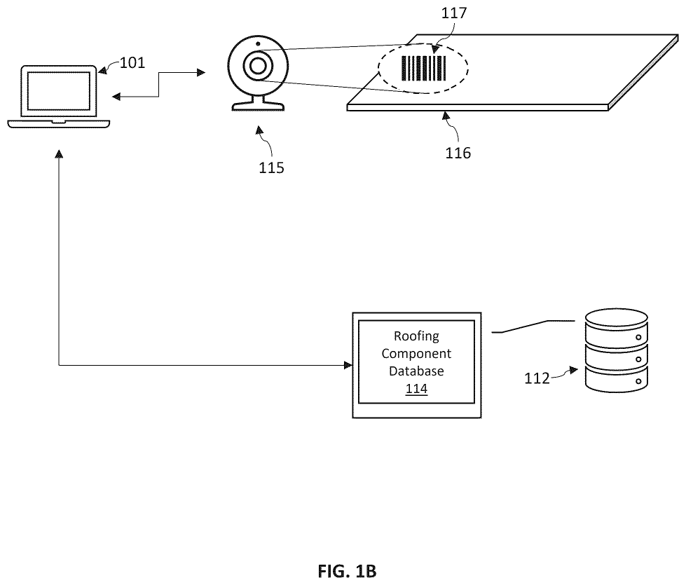

FIGS. 1 through 5 illustrate systems and methods of roof simulation and design, and roof construction based on such simulations and designs. The following embodiments minimize material and part waste, as well as enabling improved construction efficiency by augmenting computer-aided design tools with functionality to arrange roofing accessories (e.g., based on type and/or specific part) for an optimal layout and to arrange staging of the roofing accessories in advance of or during construction for efficient construction. Thus, embodiments detailed herein improve computer-aided design tools for roof design, e.g., via a plug-in, extension, add-on or other modification, to enable the computer-aided design tools to create, from a computer-aided design drawing or other image of a roof, a roof layout, a staging layout and/or a bill-of-materials.

FIG. 1A is a block diagram of an exemplary computer-based system for roof design in accordance with one or more embodiments of the present disclosure.

In some embodiments, roof and roofing system design and construction can include choosing the appropriate materials and roofing accessories for the roof. In some embodiments, variations in roofing accessories may make one roofing component a more optimal design than another, such as, e.g., installing shingles directly on a roofing deck or installing an underlayment on the roofing deck with the shingles installed on the underlayment. Moreover, there may be variations in performance and part characteristics of individual parts of the same roofing component type. Such variation may be improve or degrade the performance of a roofing system on a roof.

In some embodiments, a data storage 112 may, in a roofing component database 114, record performance characteristics and/or other part characteristics of individual unique roofing component parts.

In some embodiments, the roofing component database 114 may includes one or more local and/or remote data storage solutions such as, e.g., local hard-drive, solid-state drive, flash drive, database or other local data storage solutions or any combination thereof, and/or remote data storage solutions such as a server, mainframe, database or cloud services, distributed database or other suitable data storage solutions or any combination thereof. In some embodiments, the roofing component database 114 may include, e.g., a suitable non-transient computer readable medium such as, e.g., random access memory (RAM), read only memory (ROM), one or more buffers and/or caches, among other memory devices or any combination thereof.

In some embodiments, “database” refers to an organized collection of data, stored, accessed or both electronically from a computer system. The database may include a database model formed by one or more formal design and modeling techniques. The database model may include, e.g., a navigational database, a hierarchical database, a network database, a graph database, an object database, a relational database, an object-relational database, an entity-relationship database, an enhanced entity-relationship database, a document database, an entity-attribute-value database, a star schema database, or any other suitable database model and combinations thereof. For example, the database may include database technology such as, e.g., a centralized or distributed database, cloud storage platform, decentralized system, server or server system, among other storage systems. In some embodiments, the database may, additionally or alternatively, include one or more data storage devices such as, e.g., a hard drive, solid-state drive, flash drive, or other suitable storage device. In some embodiments, the database may, additionally or alternatively, include one or more temporary storage devices such as, e.g., a random-access memory, cache, buffer, or other suitable memory device, or any other data storage solution and combinations thereof.

Depending on the database model, one or more database query languages may be employed to retrieve data from the database. Examples of database query languages may include: JSONiq, LDAP, Object Query Language (OQL), Object Constraint Language (OCL), PTXL, QUEL, SPARQL, SQL, XQuery, Cypher, DMX, FQL, Contextual Query Language (CQL), AQL, among suitable database query languages.

The database may include one or more software, one or more hardware, or a combination of one or more software and one or more hardware components forming a database management system (DBMS) that interacts with users, applications, and the database itself to capture and analyze the data. The DBMS software additionally encompasses the core facilities provided to administer the database. The combination of the database, the DBMS and the associated applications may be referred to as a “database system”.

In some embodiments, the roofing component database 114 may be configured interact and/or to store data in one or more private and/or private-permissioned cryptographically-protected, distributed databased such as, without limitation, a blockchain (distributed ledger technology), Ethereum (Ethereum Foundation, Zug, Switzerland), and/or other similar distributed data management technologies. For example, as utilized herein, the distributed database(s), such as distributed ledgers ensure the integrity of data by generating a chain of data blocks linked together by cryptographic hashes of the data records in the data blocks. For example, a cryptographic hash of at least a portion of data records within a first block, and, in some cases, combined with a portion of data records in previous blocks is used to generate the block address for a new digital identity block succeeding the first block. As an update to the data records stored in the one or more data blocks, a new data block is generated containing respective updated data records and linked to a preceding block with an address based upon a cryptographic hash of at least a portion of the data records in the preceding block. In other words, the linked blocks form a blockchain that inherently includes a traceable sequence of addresses that can be used to track the updates to the data records contained therein. The linked blocks (or blockchain) may be distributed among multiple network nodes within a computer network such that each node may maintain a copy of the blockchain. Malicious network nodes attempting to compromise the integrity of the database must recreate and redistribute the blockchain faster than the honest network nodes, which, in most cases, is computationally infeasible. In other words, data integrity is guaranteed by the virtue of multiple network nodes in a network having a copy of the same blockchain. In some embodiments, as utilized herein, a central trust authority for sensor data management may not be needed to vouch for the integrity of the distributed database hosted by multiple nodes in the network.

In some embodiments, a distributed blockchain-type ledger implementation of the roofing component database 114 may be configured to utilize smart contracts, which are computer processes that facilitate, verify and/or enforce negotiation and/or performance of one or more particular activities among users/parties. For example, an exemplary smart contract may be configured to be partially or fully self-executing and/or self-enforcing. In some embodiments, the exemplary inventive asset-tokenized distributed blockchain-type ledger implementations of the present disclosure may utilize smart contract architecture that can be implemented by replicated registries of the roofing component database 114 and contract execution using cryptographic hash chains and Byzantine fault tolerant replication. For example, each node in a peer-to-peer network or blockchain distributed network may act as a roofing component database 114 or a part of the roofing component database 114, thereby executing changes of status, performance, condition or other characteristic of each roofing component part according to sets of predetermined rules that govern transactions on the network. For example, each node may also check the work of other nodes and in some cases, as noted above, function as miners or validators.

In some embodiments, the terms “cloud,” “Internet cloud,” “cloud computing,” “cloud architecture,” and similar terms correspond to at least one of the following: (1) a large number of computers connected through a real-time communication network (e.g., Internet); (2) providing the ability to run a program or application on many connected computers (e.g., physical machines, virtual machines (VMs)) at the same time; (3) network-based services, which appear to be provided by real server hardware, and are in fact served up by virtual hardware (e.g., virtual servers), simulated by software running on one or more real machines (e.g., allowing to be moved around and scaled up (or down) on the fly without affecting the end user). The aforementioned examples are, of course, illustrative and not restrictive.

In some embodiments, the roofing component database 114 may include performance data and/or condition data for each unique roofing component part, where each unique roofing component part refers to a unique individual item, such as a particular shingle, tile, solar shingle, solar panel, active shingle (e.g., a shingle having electronic components integrated therein), ridge cap, ridge vent, roof vent, underlayment, waterproof membrane, antenna, and any other roofing component.

In some embodiments, the roofing component database 114 may index a record associated with a particular unique roofing component part 116 according to an associated unique roofing component part identifier. In some embodiments, the unique roofing component part identifier may include, e.g., a part/model number and/or name, a unique serial number, or other identifier identifying the particular unique roofing component part 116 or any combination thereof.

In some embodiments, the performance data may include, e.g., rated temperature range, rated load capacity, rated impact limit, rated efficiency, rated waterproofing measure, measured temperature range, measured load capacity, measured impact limit, measured efficiency, measured/tested waterproofing measure, average defect(s) quantity, measured defect(s) quantity, quality control results, among other performance data or any combination thereof. In some embodiments, the performance data may include mechanical performance, such as, e.g., rated load capacity, rated weatherproofing capacity (e.g., waterproofing and/or wind proofing, etc.), rated insulation performance, rated temperature range, rated lifetime, measured load capacity, measured weatherproofing capacity (e.g., waterproofing and/or wind proofing, etc.), measured insulation performance, measured temperature range, average defect(s) quantity, measured defect(s) quantity, time-based performance change, usage-based performance change, quality control results, or other mechanical accessory performance metric or any combination thereof.

In some embodiments, where the particular unique roofing component part 116 is an active roofing component, such as a solar roofing component, the performance data may include, e.g., rated solar efficiency, rated power efficiency, measure solar efficiency, measured power efficiency, rated peak solar power generation, measured peak solar power generation, rated average solar power generation, measured average solar power generation, rated voltage, measured voltage, rated amperage, measured amperage, time-based performance change, usage-based performance change, quality and/or performance binning, Local and Regional Permitting data sets, such as required foot setbacks or activation requirements, or other active accessory performance metric or any combination thereof. In some embodiments, the performance data may include electronic performance, such as, e.g., rated processing speed, rated throughput, rated efficiency, measured processing speed, measured throughput, measured efficiency, average defect(s) quantity, measured defect(s) quantity, time-based performance change, usage-based performance change, quality and/or performance binning, quality control results, or other electronic accessory performance metric or any combination thereof.

In some embodiments, the performance and/or mechanical data of the particular unique roofing component part 116 may be tracked through time based on updates to the performance data and/or mechanical data. In some embodiments, to reference and/or update the record associated with the particular unique roofing component part 116, a user may employ a user computing device 101 to provide the associated unique roofing component part identifier of the particular unique roofing component part 116.

In some embodiments, the user computing device 101 may include or be incorporated, partially or entirely into at least one personal computer (PC), laptop computer, ultra-laptop computer, tablet, smartphone, portable computer, handheld computer, palmtop computer, personal digital assistant (PDA), cellular telephone, combination cellular telephone/PDA, television, smart device (e.g., smart phone, smart tablet or smart television), mobile internet device (MID), messaging device, data communication device, edge computing device, Internet-of-Things (IOT) device, and so forth.

In some embodiments, the user may manually input the unique roofing component part identifier, e.g., via alphanumeric input using a suitable input device, such as a keyboard, mouse, touch-enabled display, gesture control, etc., In some embodiments, the user computing device 101 may automatically obtain the unique roofing component part identifier via an imaging device 115. In some embodiments, the unique roofing component part identifier may include, e.g., a machine-readable code 117 encoding the unique roofing component part identifier. In some embodiments, the machine-readable code 117 may include, e.g., a barcode, a quick reference (QR) code, or other suitable visible encoding. In some embodiments, the user computing device 101 may automatically obtain the unique roofing component part identifier via a wireless reader device, such as, e.g., a radio-frequency identification (RFID) reader, a near field communication (NFC) reader, a Bluetooth® receiver, a WiFi receiver, or other suitable wireless reader device configured to read data encoded in a wireless transmission device. In some embodiments, the wireless transmission device may include, e.g., an RFID tag (passive and/or active), an NFC tag, a Bluetooth® transmitter, a WiFi transmitter, a Zigbee transmitter, a Z-Wave transmitter, an ORAN transmitter, an Ultra-Wide Band (UWB) transmitter, a LoRaWAN transmitter or other suitable wireless transmission device configured to convey a wireless signal encoding the unique roofing component part identifier, or any combination thereof. In some embodiments, purely for illustration, the user computing device 101 is depicted as obtaining the unique roofing component part identifier via the image capture device 115 to capture an image of the machine-readable code 117.

In some embodiments, the user computing device 101 may automatically detect the presence of the particular unique roofing component part 116 and automatically read the machine-readable code 117, e.g., via NFC, RFID, Bluetooth, WiFi, Zigbee, Z-Wave, LoRaWAN, ORAN, etc. Upon reading the machine-readable code 117, the user computing device 101 may automatically register the particular unique roofing component part 116 with the roofing component database 114.

Alternatively, or additionally, in some embodiments, the unique roofing component part identifier may be automatically registered with the roofing component database 114. In some embodiments, the particular unique roofing component part 116 may include, e.g., an embedded computing device, such as an edge computing device, Internet-of-Things (IOT) device. The embedded computing device may include, e.g., a wireless communication connection, such as, e.g., WiFi, Zigbee, Z-Wave, 5G, 4G, 3G, or other data and/or cellular connection. As a result, upon installation (e.g., upon being provided with power or a power connection, or upon manual activation during installation), the particular unique roofing component part 116 may use the embedded computing device to connect with the roofing component database 114, e.g., using a suitable wireless communication connection over a suitable network (e.g., WiFi network, Ethernet network, Local Area Network (LAN), IoT or smart home network, the Internet, or other suitable network or any combination thereof).

In some embodiments, upon receiving the unique roofing component part identifier, the user computing device 101 and/or the embedded computing device may upload the unique roofing component part identifier using, e.g., a suitable database query, to identify and access the record associated with the particular unique roofing component part 116 in the roofing component database 114. In some embodiments, the user computing device 101 may upload the unique roofing component part identifier via, e.g., a suitable network. In some embodiments, the network may include a suitable network type, such as, e.g., a local-area network (LAN), a wide-area network (WAN) or other suitable type. In some embodiments, a LAN may connect computers and peripheral devices in a physical area, such as a business office, laboratory, or college campus, by means of links (wires, Ethernet cables, fiber optics, wireless such as Wi-Fi, etc.) that transmit data. In some embodiments, a LAN may include two or more personal computers, printers, and high-capacity disk-storage devices called file servers, which enable each computer on the network to access a common set of files. LAN operating system software, which interprets input and instructs networked devices, may enable communication between devices to: share the printers and storage equipment, simultaneously access centrally located processors, data, or programs (instruction sets), and other functionalities. Devices on a LAN may also access other LANs or connect to one or more WANs. In some embodiments, a WAN may connect computers and smaller networks to larger networks over greater geographic areas. A WAN may link the computers by means of cables, optical fibers, or satellites, or other wide-area connection means. In some embodiments, an example of a WAN may include the Internet.

In some embodiments, the user computing device 101 may upload the unique roofing component part identifier using a suitable network communication technology, including, e.g., a suitable routing/communication protocol (e.g., hypertext transport protocol (HTTP), etc.), and/or a suitable interfacing technology, such as, e.g., an application programming interface (API). In some embodiments, the API may include, e.g., a computing interface that defines interactions between multiple software intermediaries. An “application programming interface” or “API” defines the kinds of calls or requests that can be made, how to make the calls, the data formats that should be used, the conventions to follow, among other requirements and constraints. An “application programming interface” or “API” can be entirely custom, specific to a component, or designed based on an industry-standard to ensure interoperability to enable modular programming through information hiding, allowing users to use the interface independently of the implementation.

In some embodiments, in response to the unique roofing component part identifier, the roofing component database 114 may return the record associated with the particular unique roofing component part 116. In some embodiments, user computing device 101 may then present a suitable graphical user interface (GUI) for presenting the record to the user. In some embodiments, the GUI may provide user interface elements for viewing and/or editing characteristics stored in the record, including, e.g., the performance data and/or the mechanical data associated with the particular unique roofing component part 116.

In some embodiments, where the GUI provides user interface elements for editing characteristics of the particular unique roofing component part 116, the user may select and/or input modifications to the characteristics, such as, e.g., a current performance according to most recent measurements, a current mechanical condition, a current state (e.g., brand new, installed, uninstalled, reused/reinstalled, etc.), among other characteristics or any combination thereof. In some embodiments, each edit may be appended to the record in order to provide a timeline of the lifetime of the particular unique roofing component part 116.

For example, when selected for a particular roofing system, the user may scan the machine-readable indicia 117 with the imaging device 115 via the user computing device 101. In some embodiments, the user computing device 101 may upload the unique roofing component part identifier encoded in the machine-readable indicia 117 to access the record and the characteristics stored therein. The user may then edit the record to indicate that a status as installed upon installing the particular unique roofing component part 116 in the roofing system. In some embodiments, the user may then re-scan the machine-readable indicia 117 to access the record and update changes to the characteristics including performance data and/or mechanical data, or any change in status, such as a time at which the particular unique roofing component part 116 is uninstalled from the roofing system (e.g., to be replaced with a new or different unique roofing component part). In some embodiments, where the particular unique roofing component part 116 may still be employed in a roofing system based on the most recent performance data and/or mechanical data upon uninstallation based on the record, the particular unique roofing component part 116 may be recycled and selected for a new roofing system (e.g., to be sold at a reduced cost or reused by the owner of the original roofing system, etc.). Thus, the particular unique roofing component part 116 may be recycled one or more times, with each status change including each installation and each uninstallation recorded in the record stored in the roofing component database 114. Accordingly, the roofing component database 114 may record a full lifecycle of each unique roofing component part, including solar roofing component parts, active roofing component parts and/or inactive roofing component parts.

FIG. 1B is a block diagram of an exemplary computer-based system for roof design in accordance with one or more embodiments of the present disclosure.

In some embodiments, in response to a roof design request 103, a roof design system 100 may produce roof designs 105 based on a predicted performance of a particular roof construction staging using the roofing component database 114 of data for roofing accessories. The data for roofing accessories may include accessory specifications and performance data for each roofing component available, including particular individual roofing component parts or roofing component types or any combination thereof. Such roofing accessories include one or more, e.g., solar roofing component(s) (e.g., solar panel(s), solar shingle(s), solar panel(s)/shingle(s) parts, electrical accessory(s), etc.), shingle(s), underlayment(s), waterproof membrane(s), decking, roofing component(s)/accessory(ies) having integrated and/or embedded electronic accessories, antenna(s), roofing cap(s), laminate roofing component(ies), roofing sheet(s), ridge cap(s), ridge vent(s), roofing frame(s) and the like, or any combination thereof.

In some embodiments, the roofing component database 114 may include manufacturing-related data for each unique roofing component. In some embodiments, the manufacturing-related data may include, e.g., temperature during manufacturing, humidity during manufacturing, time of manufacture, time and/or duration to complete manufacturing, line speed, process information, present during manufacturing, quality assurance status, production run identifier, among manufacturing-related data or any combination thereof.

In some embodiments, the roof design system 100 may produce roof designs 105 including, e.g., a roofing system, a comprehensive material and accessory list for a full roofing system, staging of material and/or accessories for constructing the roofing system (e.g., based on the comprehensive list), time and cost projections (e.g., based on the comprehensive list and/or the staging, among other roof design data or any combination thereof.

Herein, the term “staging” refers to the positioning and timing of positioning of roofing accessories and/or other roofing materials and/or components in preparation for construction of the roofing system.

Some embodiments of the present disclosure relate to at least one roofing component. Some embodiments of the present disclosure include a plurality of roofing accessories. Some embodiments of the present disclosure include at least three roofing accessories. Some embodiments of the present disclosure include at least five roofing accessories. Some embodiments of the present disclosure include at least ten roofing accessories. Some embodiments of the present disclosure include at least fifty roofing accessories. Some embodiments of the present disclosure include at least one hundred roofing accessories. Some embodiments of the present disclosure include at least one-thousand roofing accessories.

In some embodiments, there are 1 to 10,000 roofing accessories. In some embodiments there are 1 to 5000 roofing accessories. In some embodiments, there are 1 to 1000 roofing accessories. In some embodiments, there are 1 to 100 roofing accessories. In some embodiments, there are 1 to 50 roofing accessories. In some embodiments, there are 1 to 25 roofing accessories. In some embodiments, there are 1 to 10 roofing accessories. In some embodiments, there are 1 to 5 roofing accessories. In some embodiments, there are 1 to 2 roofing accessories.

In some embodiments, there are 2 to 10,000 roofing accessories. In some embodiments, there are 5 to 10,000 roofing accessories. In some embodiments, there are 10 to 10,000 roofing accessories. In some embodiments, there are 50 to 10,000 roofing accessories. In some embodiments, there are 100 to 10,000 roofing accessories. In some embodiments, there are 500 to 10,000 roofing accessories. In some embodiments, there are 1000 to 10,000 roofing accessories. In some embodiments, there are 5000 to 10,000 roofing accessories.

In some embodiments, there are 2 to 5000 roofing accessories. In some embodiments, there are 5 to 1000 roofing accessories. In some embodiments, there are 10 to 5000 roofing accessories. In some embodiments, there are 50 to 100 roofing accessories. In some embodiments, there are 60 to 90 roofing accessories. In some embodiments, there are 70 to 80 roofing accessories.

Non-limiting examples of the at least one electronic accessory of the at least one roofing component include: at least one antenna, at least one solar array, at least one battery, at least one computing device, at least one controller, at least one processor, the like, or any combination thereof. The at least one electronic accessory may also include one or more processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; x86 instruction set compatible processors, multi-core, or any other microprocessor or central processing unit (CPU). In various implementations, the one or more processors may be dual-core processor(s), dual-core mobile processor(s), and so forth.

In some embodiments, the roofing component database 114 may include performance data for each unique roofing component, where each unique roofing component refers to a unique part/model number and/or name, a unique serial number for a unique physical accessory, or any combination thereof. In some embodiments, the performance data may include solar performance, such as, e.g., rated temperature range, rated load capacity, rated impact limit, rated efficiency, measured temperature range, measured load capacity, measured impact limit, measured efficiency, average defect(s) quantity, measured defect(s) quantity, time-based performance change, usage-based performance change, quality and/or performance binning, quality control results, or other solar accessory performance metric or any combination thereof. In some embodiments, the performance data may include electronic performance, such as, e.g., rated processing speed, rated throughput, rated efficiency, measured processing speed, measured throughput, measured efficiency, average defect(s) quantity, measured defect(s) quantity, time-based performance change, usage-based performance change, quality and/or performance binning, quality control results, or other electronic accessory performance metric or any combination thereof. In some embodiments, the performance data may include mechanical performance, such as, e.g., rated load capacity, rated weatherproofing capacity (e.g., waterproofing and/or wind proofing, etc.), rated insulation performance, rated temperature range, rated lifetime, measured load capacity, measured weatherproofing capacity (e.g., waterproofing and/or wind proofing, etc.), measured insulation performance, measured temperature range, average defect(s) quantity, measured defect(s) quantity, time-based performance change, usage-based performance change, quality control results, or other mechanical accessory performance metric or any combination thereof.

In some embodiments, the roof design system 100 may leverage the roofing component database 114 and user input provided in the roof design request 103 to determine an optimized roof design 105 for the roof design request 103. In some embodiments, an optimized roof design 105 may include, e.g., an optimization based on any one or more of: cost and/or material minimization (e.g., via waste material minimization), construction time minimization, lifespan maximization, solar efficiency maximization of solar roofing component part(s), peak power generation maximization of solar roofing component part(s), average power generation maximization of solar roofing component part(s), minimum power generation maximization of solar roofing component part(s), or any other suitable roof optimization metric or suitable balancing thereof based on the roofing accessories needed for a roof design and/or performance thereof. Accordingly, in some embodiments, the roof design system 100 may minimize cost and waste for the roofing contractor by optimizing the roofing system design, identifying the amount of material needed, and providing the contractor with guidance on where to place the material when constructing the roof to maximize solar production and minimize labor, material waste based on data about each unique solar and non-solar roofing component and/or the specific characteristics thereof.

In some embodiments, the roof design system 100 may be a part of the user computing device 101 or may communicate with the user computing device 101 via a network, e.g., as a service based on a cloud-based software-as-a-service architecture, or any combination thereof. Thus, the roof design system 100 may include hardware and software accessories including, e.g., user computing device 101 hardware and software, cloud or server hardware and software, or a combination thereof.

In some embodiments, the roof design system 100 may include hardware accessories such as a processor 111, which may include local or remote processing accessories. In some embodiments, the processor 111 may include any type of data processing capacity, such as a hardware logic circuit, for example an application specific integrated circuit (ASIC) and a programmable logic, or such as a computing device, for example, a microcomputer or microcontroller that include a programmable microprocessor. In some embodiments, the processor 111 may include data-processing capacity provided by the microprocessor. In some embodiments, the microprocessor may include memory, processing, interface resources, controllers, and counters. In some embodiments, the microprocessor may also include one or more programs stored in memory.

Similarly, the roof design system 100 may include the storage 112, such as one or more local and/or remote data storage solutions such as, e.g., local hard-drive, solid-state drive, flash drive, database or other local data storage solutions or any combination thereof, and/or remote data storage solutions such as a server, mainframe, database or cloud services, distributed database or other suitable data storage solutions or any combination thereof. In some embodiments, the storage 112 may include, e.g., a suitable non-transient computer readable medium such as, e.g., random access memory (RAM), read only memory (ROM), one or more buffers and/or caches, among other memory devices or any combination thereof.

In some embodiments, the terms “cloud,” “Internet cloud,” “cloud computing,” “cloud architecture,” “edge compute,” “Internet-of-Things,” “IoT,” and similar terms correspond to at least one of the following: (1) a large number of computers connected through a real-time communication network (e.g., Internet); (2) providing the ability to run a program or application on many connected computers (e.g., physical machines, virtual machines (VMs)) at the same time; (3) network-based services, which appear to be provided by real server hardware, and are in fact served up by virtual hardware (e.g., virtual servers), simulated by software running on one or more real machines (e.g., allowing to be moved around and scaled up (or down) on the fly without affecting the end user). The aforementioned examples are, of course, illustrative and not restrictive.

In some embodiments, the roof design system 100 may implement computer engines including, e.g., a roof modelling engine 120 to model the roof of a structure, a staging engine 130 to model and optimize roof layouts, a material selection engine 140 to generate a roof design plan based on the roof layouts and a material selection engine 150 to generate a list of materials and/or tools for constructing the roof design plan. In some embodiments, the terms “computer engine” and “engine” identify at least one software accessory and/or a combination of at least one software accessory and at least one hardware accessory which are designed/programmed/configured to manage/control other software and/or hardware accessories (such as the libraries, software development kits (SDKs), objects, etc.).

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; x86 instruction set compatible processors, multi-core, or any other microprocessor or central processing unit (CPU). In various implementations, the one or more processors may be dual-core processor(s), dual-core mobile processor(s), and so forth.

Examples of software may include software accessories, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

In some embodiments, each of the roof modelling engine 120, the staging engine 130, the material selection engine 140 and the roof design execution engine 150 may include dedicated and/or shared software accessories, hardware accessories, or a combination thereof. For example, each of the roof modelling engine 120, the staging engine 130, the material selection engine 140 and the roof design execution engine 150 may include a dedicated processor and storage. However, in some embodiments, any one or more of the roof modelling engine 120, the staging engine 130, the material selection engine 140 and the roof design execution engine 150 may share hardware resources, such as the processor 111 and storage 112 of the roof design system 100 via, e.g., a bus 113. In some embodiments, the roof modelling engine 120, the staging engine 130, the material selection engine 140 and the roof design execution engine 150 may use any combination of dedicated and/or shared hardware and/or software resources for executing via one or more processor(s) the tasks, services, functions, etc. thereof.

In some embodiments, the roof modelling engine 120 may ingest the roof design request 103 and create a virtual roof model by modelling each roof plane on a roof associated with the roof design request 103. Accordingly, in some embodiments, the roof design request 103 may include and/or reference roof-related data for a particular roof of a particular physical structure. In some embodiments, the roof design request 103 may include, e.g., one or more roof designs for new construction of a roof, repair of a roof, or other construction project for a particular roof. The roof design may include parameters defining a roof or a portion thereof, including dimensions, orientations, slopes, existing and/or designed features (e.g., chimney, roof vent, skylights, among other structures and/or formations or any combination thereof). The roof design may be a two-dimensional and/or three-dimensional image of a roof, a two-dimensional and/or three-dimensional digital model of the roof, a computer-aided design (CAD) drawing and/or model of the roof, a schematic, one or more data objects (e.g., key: value pairs, tables, arrays, etc.) specifying the parameters, or other form of representing the parameters of the roof design. For example, the roof design may include imagery of an existing roof or blueprint of a planned roof.

In some embodiments, the roof design may be produced via a roof CAD tool 160, e.g., installed on or provided as a service (e.g., cloud-based software-as-a-service) to the user computing device 101. Accordingly, the roof design system 100 may be integrated into the roof CAD tool 160 as part of the software of the roof CAD tool 160. In other embodiments, the roof design system 100 may be a separate software package, application and/or service from the roof CAD tool 160. For example, the roof design system 100 may receive a roof design created in the roof CAD tool 160, e.g., via user manipulate of a file containing the roof design. In another example, the roof design system 100 may be an add-on, plug-in or extension for the roof CAD tool 160.

In some embodiments, the terms “add-on,” “plug-in” and “extension” general refer to separate software from a host program, where the separate software provides new, different and/or modified capabilities and/or functions to the host program. Indeed, embodiments of the present disclosure may include the roof CAD tool 160 being an existing CAD program, such as, e.g., AutoCAD™, Solidworks™, SketchUp™, or other CAD program, and the roof design system 100 may form an add-on to the existing CAD program to provide roof modelling, staging optimization, material selection and roof design execution functionality to the existing CAD program, thus improving upon the existing CAD program for roof design and staging optimization.

In some embodiments, such as where the roof design is an image and/or a CAD drawing, the roof modelling engine 120 may obtain the roof design associated with the roof design request 103 to model each roof plane of the roof. In some embodiments, modelling each roof plane may include determining dimensions of each roof plane to, e.g., characterize the shape of each roof plane. For example, the roof modelling engine 120 may determine, e.g., height, width, length, pitch, among other dimensions or any combination thereof. In some embodiments, the term “roof plane” refers to an individual planar portion of a roof, where a roof may have one or more roof planes connected by edges and/or ridges between adjacent roof planes.

In some embodiments, the roof modelling engine 120 may obtain the roof design and create a user editable model of the roof to allow the user to specify roofing accessories and the positioning thereof on the roof. For example, the roof modelling engine 120 may include the set of roofing accessories available for a roof, e.g., including the roofing accessories in the roofing component database 114. Indeed, the roof design system 100 may integrate particular roofing component models, unique parts, types, among other catalogs of roofing accessories or any combination thereof. The roofing accessories, whether specified according to model, type, unique parts, etc., may include attributes of the roofing component, such as size, orientation constraints, whether the roofing component can be cut or otherwise reshaped/resized, among other attributes or any combination thereof.

Using the editable roof model and the available roofing accessories, a user may use the GUI on the user computing device 101 to command the roof modelling engine 120, e.g., as an add-on function to the roof CAD tool 160 or as a separate program/cloud service, to select and position roofing accessories on the roof model. Positioning may include location on a roof plane of the roof as well as a layer within multiple layers of roofing accessories. For example, an underlayment may be situated between roof decking and shingles. The roof modelling engine 120 may include the functionality to specify the layering of such roofing accessories, such as a bottom layer of roof decking, with underlayment positioned on the roof decking, and shingles positioned on the underlayment, including the overlapped layering of rows of shingles. Thus, a user may specify X and Y positioning along X and Y axes within a plane defined by a roof plane, as well as layered positioning.

In some embodiments, based on the user selection of the roofing accessories and definition of the positioning, the roof modelling engine 120 may generate an arrangement of the selected roofing accessories. In some embodiments, generating the arrangement may include determining the dimensions of a selected roofing component and whether the selected roofing component can be resized. Based thereon, thereon, the selected roofing component may be defined with respect to the roof model to cover an area associated with the positioning. In some embodiments, the selected roofing component may be produced in preset sizes that do not match the dimensions of the roof and/or the area on the roof associated with the positioning. Accordingly, the roof modelling engine 120 may determine how many individual components of the selected roofing component is needed to fill the area, and a size and/or shape to which each individual component is to be cut to trim excess that goes beyond the area. As a result, the roof modelling engine 120 may generate the arrangement and cut lines of each selected roofing component to be installed on the roof.

In some embodiments, generating the arrangement may include accounting for configured and/or predefined constraints and requirements on the arrangement of roofing accessories and/or instances thereof, including the relative placement of roofing accessories. For example, there may be a predetermined minimum and/or maximum amount of overlap between instances of shingles and/or underlayment's or other roofing accessories. Thus, the roofing modeling engine 120 may generate an arrangement that includes an overlap within such minimum and/or maximum values.

For example, underlayment may be produced in rolls having a predetermined width and length, and the positioning selected by the user may define an entire roof plane over which to position underlayment. Accordingly, the roof modelling engine 120 may determine the number of rolls of underlayment needed to cover the roof plane based on the dimensions of the roof plane and the dimensions of the underlayment in the roll.

In some embodiments, the user may specify, via the GUI, the arrangement, dimensions and/or cut lines of each roofing component, e.g., via drag and drop of representations of each roofing component. In some embodiments, for example, the GUI may provide to-scale representations of a roofing component part and of the roof design. The user may, upon selection of the roofing component, place an instance of the roofing component part in a desired location on the roof model to cover a desired area of the roof based on visual depiction of the size and shape of the roofing component and of the roof. In some embodiments, the GUI may include functionality to facilitate user positioning such as snap-to functionality where edges of two instances of a roofing component are automatically aligned when one is brought within a certain proximity of the other in the GUI.

In another example, based on the roofing component, the roofing modelling engine 120 may provide the GUI with constraints on the arrangement of a roofing component relative to other roofing accessories and/or other instances of the same roofing component. For example, underlayment may have a predetermined allowable amount of overlap between adjacent instances of an underlayment roll, or similarly with shingles there may be a predetermined maximum allowable overlap between instances of shingles. As a result, the roofing modelling engine 120 may prevent the user from positioning roofing accessories and/or instances thereof in such a way as to violate the constraints, such as the maximum allowable overlap.

In some embodiments, the roof modelling engine 120 may determine dimensions of each roof plane based on, e.g., measurements provided by the roof-related data. Additionally or alternatively, the roof modelling engine 120 may implement one or more machine learning models to process images and/or CAD drawings of the roof. In some embodiments, the one or more machine learning models may include image segmentation, object detection and/or object recognition tasks. Accordingly, the one or more machine learning models may be trained to recognize one or more roofing accessories, materials and/or hardware or other roof features of a roof such as, e.g., vent stack(s), skylight(s), chimney(s), ridge vent(s), antenna(s), laminate roofing component(ies), roofing sheet(s), ridge cap(s), roofing frame(s), and the like or any combination thereof. In some embodiments, the one or more machine learning models may also or alternatively be trained to recognize one or more obstructions that are situated over the roof, such as, e.g., trec(s), power line(s), nearby structure(s), among other objects that may obstruct a roof plane from sunlight.

In some embodiments, the one or more machine learning models may include algorithms for predicting spatial dimensions based on the visual/CAD images, such as distances between roof features on the roof and to ends of each roof plane. Accordingly, the one or more models may include regression based algorithms for interpolating spatial data for each roof plane such as, e.g., roof plane area, roof plane length, roof plane width, roof plane height, roof plane pitch angle, roof feature height, roof feature length, roof feature width, roof feature distance from one or more particular roof plane edge(s), roof feature distance from a roof ridge, etc., and/or for interpolating spatial data for measurements of relative spatial relationships between roof planes, such as, orientation angle between a first and a second roof plane, etc.

In some embodiments, the dimensions of each roof plane may be set in a three-dimensional coordinate system including each roof plane of the roof. Thus, the roof modelling engine 120 may translate the measurements of the roof-related data, the spatial dimensions from the one or more machine learning models, or a combination thereof, to construct a three-dimensional model of the roof including each roof plane of the roof and each obstruction. In some embodiments, the three-dimensional model may include, e.g., virtual representation of measurements, locations and/or objects set in a virtual three-dimensional coordinate system.

In some embodiments, the roof modelling engine 120 may orient the three-dimensional model to reflect an orientation of the roof and each roof plane thereof. For example, the three-dimensional model may include, e.g., an orientation according to cardinal directions (north, west, cast, south, etc.), a geospatial location (e.g., via latitude-longitude, address, etc.), among other location and orientation information.

In some embodiments, the staging engine 130 may retrieve the roof model from the roof modelling engine 120, either directly upon output by the roof modelling engine 120, or via a stored three-dimensional model stored, e.g., in the storage 112. In some embodiments, the staging engine 130 may ingest the roof model, including the dimensions of each selected and/or positioned roofing component, the layering of roofing accessories, cut lines of the roofing accessories, the roof plane dimensions, etc.

In some embodiments, the staging engine 130 may develop a staging arrangement for the roofing accessories defining the staging of the roofing accessories at the site of the roof in preparation for construction of the roof system. In some embodiments, the staging engine 130 may provide to the GUI functionality for the user to specify staging, including where to place certain roofing accessories, in what order to arrange the roofing accessories to case access (e.g., sequentially moving the roofing component parts during construction), order of delivery of roofing accessories, among other staging arrangements or any combination thereof.

To facilitate creating optimal staging arrangements that reduce time of workers to obtain a needed roofing component part at the appropriate time during construction, the roof design may include the locations of certain non-roof features. Such non-roof features may include, e.g., dumpster location, a driveway, abutting structures, tree locations, ladder placement, among other features or any combination thereof that may limit, impede, or facilitate access to the roof at positions around the roof.

In some embodiments, the staging engine 130 may automatically determine the staging arrangement based on the roofing accessories, number of parts thereof, positioning and layering of roofing accessories, positioning of features of the roof and/or the positioning of the non-roof features. For example, the staging engine 130 may create a staging arrangement that defines staging roofing accessories prior to installation at positions around the roof closes to their respectively positioning on the roof. Similarly, the staging engine 130 may create a staging arrangement that defines relative times to stage roofing accessories prior to installation at positions around the roof based on an order of installation of each roofing component and/or part thereof according to the positioning and layering of the roofing accessories in the roof model.

In some embodiments, the staging engine 130 may utilize one or more artificial intelligence (AI) and/or machine learning (ML) techniques to automatically create the staging arrangement, including the positioning and ordering of roofing accessories and/or parts thereof in preparation for installation. The AI and/or ML techniques may include, but is not limited to, decision trees, boosting, support-vector machines, neural networks, nearest neighbor algorithms, Naive Bayes, bagging, random forests, and the like. In some embodiments and, optionally, in combination of any embodiment described above or below, an exemplary neutral network technique may be one of, without limitation, feedforward neural network, radial basis function network, recurrent neural network, convolutional network (e.g., U-net) or other suitable network. In some embodiments and, optionally, in combination of any embodiment described above or below, an exemplary implementation of Neural Network may be executed as follows:
a. define Neural Network architecture/model,
b. transfer the input data to the exemplary neural network model,
c. train the exemplary model incrementally,
d. determine the accuracy for a specific number of timesteps,
c. apply the exemplary trained model to process the newly-received input data,
f. optionally and in parallel, continue to train the exemplary trained model with a predetermined periodicity.

In some embodiments and, optionally, in combination of any embodiment described above or below, the exemplary trained neural network model may specify a neural network by at least a neural network topology, a series of activation functions, and connection weights. For example, the topology of a neural network may include a configuration of nodes of the neural network and connections between such nodes. In some embodiments and, optionally, in combination of any embodiment described above or below, the exemplary trained neural network model may also be specified to include other parameters, including but not limited to, bias values/functions and/or aggregation functions. For example, an activation function of a node may be a step function, sine function, continuous or piecewise linear function, sigmoid function, hyperbolic tangent function, or other type of mathematical function that represents a threshold at which the node is activated. In some embodiments and, optionally, in combination of any embodiment described above or below, the exemplary aggregation function may be a mathematical function that combines (e.g., sum, product, etc.) input signals to the node. In some embodiments and, optionally, in combination of any embodiment described above or below, an output of the exemplary aggregation function may be used as input to the exemplary activation function. In some embodiments and, optionally, in combination of any embodiment described above or below, the bias may be a constant value or function that may be used by the aggregation function and/or the activation function to make the node more or less likely to be activated.

Accordingly, the staging engine 130 may determine positional and/or layering information from the roof model, as well as roofing component data for each part of each roofing component of the roof model, and utilize the AI and/or ML techniques to output position and/or order data representative of the position and relative ordering of each roofing component and/or roofing component part around the roof. To do so, the staging engine 130 may access the roofing component database 114. In some embodiments, the roofing component database 114 may include specifications for each roofing component part, each roofing component model, each roofing component type, among other forms roofing component specifications or any combination thereof. In some embodiments, the roofing component(ies) may include solar roofing accessories, active roofing accessories and/or inactive roofing accessories. In some embodiments, the solar roofing accessories may include one or more solar-based devices configured for installation on a roof, such as photovoltaic devices, including, e.g., a solar shingle, solar panel, a solar panel attachment, among other solar-based devices configured for installation on a roof. In some embodiments, the active roofing accessories may include any suitable electronic components configured to be integrated into roofing accessories for installation on a roof, such as integrated roofing accessories including, e.g., 5G radio integrated roofing accessories, sensor integrated roofing accessories, computing/networking device integrated roofing accessories, or any other suitable roofing component having active (e.g., electronic) components integrated therein or any combination thereof. In some embodiments, the inactive roofing accessories may include “conventional” roofing accessories, such as, e.g., shingles, waterproofing membranes, underlayment, roof decking, gutters, ridge vents, ridge caps, etc.

In some embodiments, the roofing component database 114 may include types of roofing accessories, including types of solar roofing accessories, such as, e.g., a solar shingle model, a solar shingle type, a solar panel model, a solar panel type, etc. In some embodiments, the term “model” may refer to a manufacturer defined model for items conforming to a particular set of characteristics (e.g., size, use, capabilities, price, etc.). In some embodiments, the term “type” may refer to any grouping of similar items according to overlap in characteristics, such as, e.g., any solar shingle having a particular form factor (e.g., matching an asphalt shingle, matching a tile shingle, constructed of a particular type of substrate or manufacturing process, etc.), including solar shingles of multiple different manufacturer defined models.

In some embodiments, the roofing component database 114 may include records for each roofing component part type/model according to an associated roofing component part type/model identifier identifying each roofing component part type/model. In some embodiments, a manufacturer, retailer, contractor, or other administrative user may provide unique roofing component parts with associated roofing component part type/model identifiers via the user computing device 101. In some embodiments, upon entry, the user may define for a particular solar roofing component part type/model a set of specifications defining characteristics of the roofing component part type/model. In some embodiments, the set of specifications may include, e.g., roofing component type, roofing component model, dimensions, installation mounts specifying a type of connector, fastener, adapter, etc. used to install the roofing component part type/model, as well as any roofing component part type/model performance characteristics. As a result, a record of a particular roofing component part type/model may be entered into the roofing component database 114, e.g., indexed according to the roofing component part type/model identifier. A separate record may be created for each available roofing component part type/model to create an inventory of roofing component part types/models specifying characteristics including performance characteristics, dimensions, capabilities, etc.

Accordingly, in some embodiments, the staging engine 130 may simulate access to each roofing component relative to its respective install location on each roof plane, e.g., based on distance and/or obstacles (including other roofing accessories/parts staged between the install location and the roofing component), by simulating each candidate staging layout of a plurality of staging layouts. In some embodiments, the staging engine 130 may simulate each candidate staging layout using a closest unimpeded position around the roof for a set of roofing component parts relative to the install location(s) of the set of roofing component parts based on the associated roof and/or non-roof features. Thus, the simulation may include sequentially locating each roofing component part into a location in a candidate staging layout, the sequence being defined by a descending order of a performance characteristics indicative of time, proximity and/or other measure of access to the roofing accessories during installation. In some embodiments, the staging engine 130 may simulate every possible combination of roofing component parts in each candidate staging layout.

In some embodiments, the staging engine 130 may assign to each candidate staging layout a installation prediction based on the simulation(s) associated each candidate staging layout. In some embodiments, installation prediction may include, e.g., an installation score of each candidate staging layout based on, e.g., a predicted installation metric associated with the candidate staging layout that measures the degree of access to the roofing component part to be installed based on the positions and layering of the roof model. In some embodiments, the installation prediction may include, e.g., a predicted installation score for each roofing component part and/or each roofing component type/model specified in each candidate staging layout based on installation mount, dimensions, position, layer, overlap with other roofing accessories/parts, among other features affecting the performance of installation associated with each roofing component part and/or each roofing component type/model. In some embodiments, the staging engine 130 may utilize one or more machine learning models, as detailed above, to ingest the characteristics of each roofing component part and/or each solar roofing component type/model and/or the roof model of each candidate staging layout, the three-dimensional model, and the roofing-related data.

In some embodiments, the staging engine 130 may output a particular staging layout of the candidate staging layouts based on a candidate staging layout having a greatest installation prediction. In some embodiments, the particular staging layout may define the location on each roof plane of each unique solar roofing component part and each active/inactive roofing component (“non-solar roofing component parts”). The particular layout may also be defined for each unique solar roofing component part in the particular staging layout the installation score according to the location and/or ordering around the roof of each roofing component part.

In some embodiments, the material selection engine 140 may ingest the particular staging layout and access, e.g., in the storage 112, data indicative of material cost of each roofing component part, equipment associated with installation of each roofing component part, labor costs associated with installation of each roofing component part, installation time associated with each roofing component part, among other installation related data or any combination thereof to complete a weatherproof solar roof system.

In some embodiments, based on the installation related data for the particular staging layout, the material selection engine 140 may generate a list of the roofing component type, model and/or part identifiers identifying each roofing component type, model and/or part of the particular staging layout and roof model, as well as equipment, materials, labor time, labor cost, and installation costs associated with constructing the roof system on the roof. In some embodiments, the material selection engine 140 may store the roof design in the storage 112 using the roofing component type, model and/or part identifiers to reference the record of each roofing component part used in the particular layout of the roof design.

In some embodiments, the material selection engine 140 may access the roof design to generate a list of materials, components and/or tools for constructing the roof design on the roof. In some embodiments, the list of materials, may include, e.g., a type of fastener for securing each roofing component part including each unique solar roofing component part to the roof, a number of fasteners needed to secure each roofing component part including each unique solar roofing component part to the roof, brackets, adhesives, frames, raw materials (e.g., lumber, brick, stone, cement, asphalt, etc.), wiring, waterproofing, hammer, hammer type, screw driver, screw driver type, drill, drill bits, nail gun, staple gun, or any other material, component and/or tools or any combination thereof.

In some embodiments, the material selection engine 140 may include, e.g., one or more machine learning models for learning one or more materials and/or tools associated with each roofing component part of the roof design. Thus, for each roofing component part in the roof design, the material selection engine 140 may identify the associated materials/components type(s) and a quantity thereof for installing each roofing component part. In some embodiments, for some roofing component parts, such as shingles, the materials/components may be learned based on features including an area of coverage of the roofing component parts, a number of the roofing component parts in the roof design, a location and/or orientation of the virtual roof model, or other feature or any combination thereof. Similarly, in some embodiments, for solar roofing component parts and/or any other electronic roofing component parts, the materials/components may be learned based on features include a number of the solar roofing component parts and/or electronic roofing component parts, an area of coverage of the solar roofing component parts, a location and/or orientation of the virtual roof model, or other feature or any combination thereof. In some embodiments, the one or more machine learning models may be trained based on a roof type, such as, e.g., a residential roof, a commercial roof, a roof with wood decking, a roof with non-wood decking, or other type of roof or any combination thereof.

In some embodiments, the material selection engine 140 may include, e.g., a library of material rules and tool rules. In some embodiments, the material rules may include a mapping of a type and an amount of one or more materials and/or components for each solar roofing component part or other roofing component part. Thus, for each roofing component part in the roof design, the material selection engine 140 may identify the associated materials/components type(s) and a quantity thereof for installing each roofing component part. In some embodiments, for some roofing component parts, such as shingles, the materials/components may be mapped based on an area of coverage of the roofing component parts or on a number of the roofing component parts in the roof design. In some embodiments, for solar roofing component parts and/or any other electronic roofing component parts, the materials/components may be mapped based on a number of the solar roofing component parts and/or electronic roofing component parts. In some embodiments, the material rules may be based on a roof type, such as, e.g., a residential roof, a commercial roof, a roof with wood decking, a roof with non-wood decking, or other type of roof or any combination thereof.

In some embodiments, the tool rules may include a mapping of a tool or tool type for each solar roofing component part, other roofing component part and/or material. For example, specific fasteners may be mapped to particular tools (e.g., nails mapped to hammer, Philips head screw mapped to Philips head screw driver, asphalt shingle mapped to nail gun and/or staple gun, etc.). In another example, particular solar roofing component parts may be mapped to particular adhesives and/or tools (e.g., mallet, hex wrench, clamp, etc.) for installing the particular solar roofing component part. Accordingly, the tool rules may identify a list of tools needed to complete installation of the roof design based on the solar roofing accessories, the other roofing accessories and/or the associated materials/components produced by the material rules. In some embodiments, the material selection engine 140 may identify a number of each tool based on, e.g., a number of workers (e.g., input by a user via the user computing device 101), a predetermined number of workers, a roof area, a number of solar roofing component parts, a construction timeline (e.g., input by a user via the user computing device 101), among other characteristics of the construction of the roof design.

In some embodiments, the material selection engine 140 may correlate a construction timeline and a roof area to a number of workers needed for construction based on an algorithm correlating a construction time per unit area per worker for a roof construction project. Based on the number of workers, the material selection engine 140 may determine the number of tools to maximize worker production and minimize construction time. In some embodiments, the material selection engine 140 may utilize one or more machine learning models to correlate each worker to a construction time and/or construction area over a time period or other metric of productivity. In some embodiments, the correlation may be based on features such as, e.g., solar roofing component part to be installed, tool being used, materials needed, time of year, among other features or any combination thereof. Thus, a time to install each roofing component part in the roof design can be determined, and the total construction timeline can be minimized according to the time to install each roofing component part and maximum and/or minimum numbers of workers available.

In some embodiments, the material list and tool list may be added to the roof design. In some embodiments, the roof design 105 may be output to the user computing device 101 to present the roof design 105 to a user such as, e.g., a contractor, installer, manufacture, property owner or other user or any combination thereof. Thus, the roof design system 100 may produce a bill of materials and design for a solar roof system to enable a user to plan for and carry out installation with accurate and optimized layouts of unique solar roofing component parts and the associated costs, time and equipment. Thus, the roof design 105 may provide complete and comprehensive bill of materials for the entire roofing system integrating solar and non-solar roofing accessories, a design guide based on optimization of location and count of unique solar roofing component parts and non-solar roofing accessories, providing contractors with multiple solar shingle designs to meet a variety of customer goals, including solar production, cost, aesthetics, among other end uses or any combination thereof.

In some embodiments, the material list, tool list and/or particular staging layout may be provided, directly or via storage 112, to the roof design execution engine 150. The roof design execution engine 150 may reference, using the material list, the roofing component types, models and/or parts associated with the roof design to query to the roofing component database 114 for manufacturer and/or supplier data associated with each roofing component type, model and/or part. Thus, the roof design execution engine 150 may determine sourcing for each roofing component model, type and/or part of the roof design.

In some embodiments, the roof design system 100 may include one or more interfaces and/or communication methods to communicate with manufacturers and/or suppliers. Indeed, the roof design system 100 may communicate with a computing system of the manufacturer and/or supplier of each roofing component model, type and/or part via, e.g., a suitable application programming interface (API), messaging protocol, or other communication technology. In some embodiments, the communication may be communicated across, e.g., a direct interface between the roof design system 100 and the computing system of the manufacturer and/or supplier of each roofing component model or across a network (such as a local area network (LAN), wide area network (WAN), Internet, intranet, or other network and combinations thereof), or a combination thereof. In some embodiments, the connection may include, e.g., hard wired connections (e.g., fiber optic cabling, coaxial cabling, copper wire cabling, ethernet, etc.), wireless connections (e.g., WiFi, Bluetooth, Zigbee, Z-Wave, cellular networking such as 5G, 4G, Long Term Evolution (LTE), 3G, High-Speed Downlink Packet Access (HSPA), Global System for Mobile Communications (GSM), Code-division multiple access (CDMA) or other technologies, and combinations thereof), or combination thereof.

Via such communication, the roof design execution engine 150 may send to the manufacturer/supplier of each roofing component model, type and/or part, a request for the respective roofing component model(s), type(s) and/or part(s), along with staging information from the particular staging layout so as to source each roofing component model, type and/or part in an order associated with the particular staging layout. For example, where on site a particular roofing component part is staged at position in front of another roofing component part, the roof design execution engine 150 may define, based on the particular staging layout, that the particular roofing component part be delivered prior to the other roofing component part.

In some embodiments, the roof design execution engine 150 may trigger the request automatically in response to the particular staging layout. In some embodiments, the user may control the roof design execution engine 150 send the request at a scheduled time, upon selection by the user to send the request, or both. Thus, the roof design execution engine 150 may execute automatically and/or manually so as to source parts and materials for construction of the roof system.

In some embodiments, the roof design execution engine 150 may include a software application for directing an install to stage, move and/or install each roofing component based at least in part on the staging layout and list of roofing component parts. In some embodiments, the staging layout and/or roof model of the staging layout may provide location information associated with the staging and installation of each roofing component part. The roof design execution engine 150 may be configured to obtain current location information of an installer and map the current location information to the staging layout. In so doing, the roof design execution engine 150 may produce a route direction that maps a route of a particular roofing component part to an associated staging location, and/or from the associated staging location to an associated install location. Indeed, because the staging layout may include staging locations based on optimized routes to install points, as detailed above, the roof design execution engine 150 may correlate the optimized routes to associated roofing component parts staged at associated staging locations. Thus, upon map the current location of the installer, the roof design execution engine 150 may determine a next roofing component part for installation based on the location and/or ordering around the roof of each roofing component part of the staging layout and navigate the installer to the associated staging location and then to the associated install point based on the staging layout and the physical roof mapped to the staging layout.

In some embodiments, mapping a physical roof to a roof model of the staging layout for navigating a user based on the roof model can include integrating spatial data acquisition, computational modeling, and navigation technologies. As a result of the mapping of the physical roof to the roof model, or vice versa, the install can be navigated in real time to utilize the staging layout for optimized installing of roof component parts.

In some embodiments, the acquisition of roof data includes surveying the physical roof to collect information about its dimensions, features, and layout. Various tools may be employed for this purpose, including LiDAR sensors, GPS and orientation sensors, photogrammetry, and manual measurement techniques. Roof features such as ridges, valleys, chimneys, skylights, vents, and obstructions are identified and recorded during this stage.

In some embodiments, as detailed above, the creation of the roof model can include generating a digital representation of the roof based on the collected data. This representation may take the form of two-dimensional CAD drawings, three-dimensional models, or polygonal meshes. The roof model is mapped to a coordinate system, such as a Cartesian grid or geospatial coordinates, to enable precise positioning of features and navigation points. Roof features are annotated within the model, including dimensions, locations, and types.

In some embodiments, the overlaying navigation points onto the roof model can include creating a virtual grid that divides the roof into smaller units, such as one-foot by one-foot squares. A connectivity graph may be generated to represent the relationships between grid points, facilitating the calculation of optimal paths for navigation. A distance matrix can be created to measure distances between grid points, which may include Euclidean distance, Manhattan distance, or weighted distance adjusted for factors such as material weight or traversal time.

In some embodiments, the mapping the physical roof to the roof model can include aligning the physical roof with the digital model using reference points, such as GPS coordinates or fixed features. Calibration is performed to ensure accuracy by comparing measurements from the physical roof to the model and making adjustments as needed. Real-time updates may be integrated into the model using sensors to reflect changes or updates to the physical roof. For example, based on LIDAR input, e.g., from a smartphone or other device, landmarks, key points, or other physical reference points can be identified and used to align the physical roof to the digital model. Such reference points can include, e.g., one or more edges of the roof, a peak or ridge of the roof, a chimney or other roof structure, among others or any combination thereof.

In some embodiments, the navigation based on the roof model includes tracking the position of the user on the physical roof using GPS, orientation sensors, or LiDAR and optical sensors, e.g., to identify the reference points and/or other features. Routes can be generated within the roof model to optimize navigation, considering factors such as shortest path, efficient material distribution, and avoidance of obstacles. Navigation feedback can then be provided through visual indicators displayed on a device, haptic feedback signals, or audio instructions.

In some embodiments, integration with staging and installation processes can include utilizing the roof model to guide material placement and installation. Staging points can be defined within the model to optimize material distribution, and layering and positioning of materials are accounted for to ensure proper installation order and location.

In some embodiments, real-time adjustments may be made as the user moves across the roof, with the model updating the user's position and recalculating routes as necessary. Error correction is performed to provide updated instructions if deviations from the route occur.

In some embodiments, navigation logs can be recorded for reporting and analysis, and completion verification can be performed to ensure that all materials have been distributed and installed according to the staging layout. Accordingly, the roof design execution engine 150 can facilitate efficient material distribution, minimizes labor inefficiencies, and enhances safety during roof installation by mapping the physical roof to a roof model and leveraging navigation technologies.

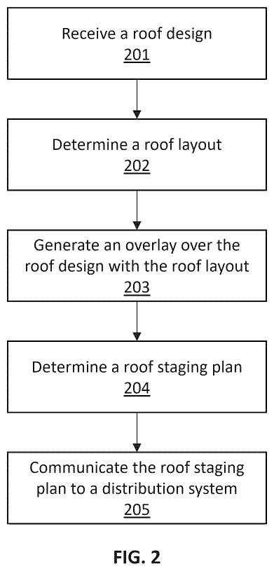

FIG. 2 illustrates a flowchart of an illustrative methodology in accordance with one or more embodiments of the present disclosure.

At step 201, receiving, via a roof computer aided design (CAD) tool, by at least one processor (e.g., the processor 112 of the roof design system 100 detailed above), an upload of a roof design representing a design of a roof. In some embodiments, the at least one roofing component and the roof design may include at least one roof feature, or at least one non-roof feature or both. The at least one roof feature may include at least one structure on the roof. The at least one non-roof feature may include at least one structure in proximity with the roof.

At step 202, determine a roof layout for the roof, the roof layout including at least one roofing component positioned on the roof. In some embodiments, determining the roof layout may include receiving, via the roof CAD tool, at least one user selection of at least one roofing component. The at least one user selection may include at least one portion of the roof design at which the at least one roofing component is to be positioned, and the portion and the roofing component each include at least one respective dimension.

In some embodiments, the user may make selected by selecting from amongst a set of selectable roofing components. A plug-in (e.g., a “staging plug-in”) to the roof CAD tool may provide the selectable set of roofing components. The selectable set of roofing components may refer to data regarding each roofing component in a storage (e.g., such as the roofing component database 114 detailed above). Thus, the roof CAD tool may be provided with the roofing components and the data thereof, including one or more dimensions for each roofing component.

The staging plug-in may further provide, via the roof CAD tool, the functionality for the user to perform the at least one user selection of the at least one roofing component from among the selectable set of roofing components.

At step 203, the roof CAD tool augmented with the staging plug-in may generate at least one roofing component overlay on the roof design such that the at least one roofing component is represented in the roof design as an overlay covering, based at least in part on the at least one dimension, at least one covered portion of the roof design corresponding to the at least one portion at which the at least one roofing component is to be positioned. Indeed, the staging plug-in may use the roof design system 100 detailed above to automatically determine the dimensions of each of the roof and the roofing component, and generate a GUI element including an overlaid representation of the roofing component overlaid on the roof design so as to visually depict the placement of the roofing component.

At step 204, a roof staging plan may be determined. The staging plug-in may generate, from the at least one roofing component overlay, at least one roof staging plan that may include a actions and an order of the actions to install the at least one roofing component on the roof. The staging plug-in may, e.g., using the staging engine 130 of the roof design system 100 detailed above, automatically generate the staging plan using one or more AI and/or ML techniques. The AI and/or ML techniques may be trained to optimize the staging plan for minimized time for installers to install the roofing component(s) according to the roof design. To do so, the AI and/or ML techniques may take into account the roof design, including both roof and non-roof features, and the position and/or layering of roofing components on the roof to assign to a pre-installed position and order of the roofing component(s). Alternatively, or in addition, the user may manually specify the staging plan via input to the GUI.

At step 205, the roof staging plan may be communicated to a distribution system, such as the system of one or more manufacturers and/or suppliers of the roofing component(s), e.g., as detailed above. The staging plan may be configured to cause the at least one distribution system to initiate the plurality of actions according to the order of the plurality of actions.

In some embodiments, the roof staging plan may include at least one dimension alteration, such as the cut lines detailed above, to the at least one roofing component based at least in part on the roof design and the at least one dimension of the at least one roofing component. Thus, the roof staging plan may be configured to instruct the distribution system to pre-cut or otherwise change the dimensions of the roofing component(s) prior to distribution to the site of the roof.

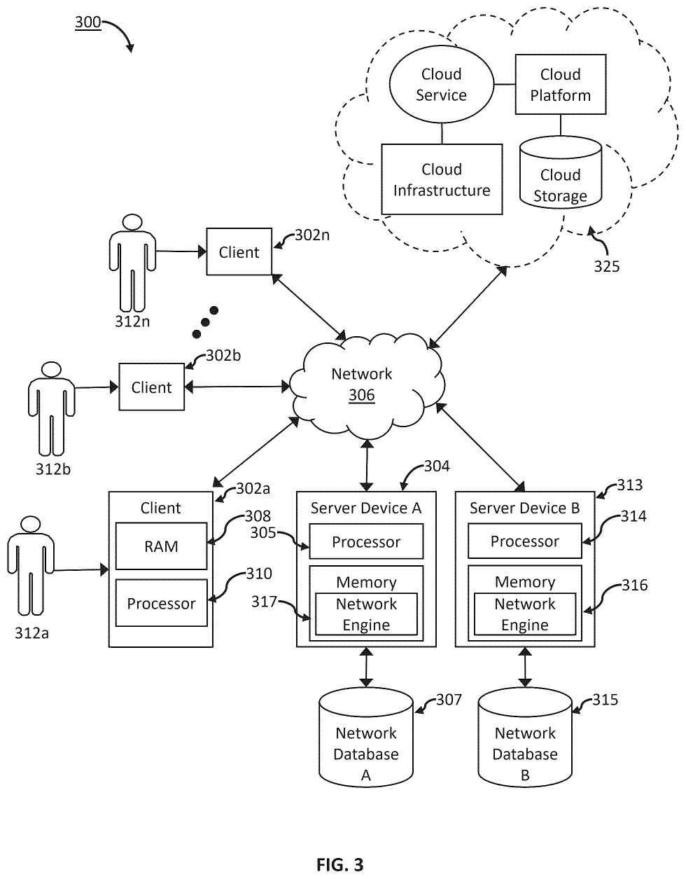

FIG. 3 depicts a block diagram of another exemplary computer-based system and platform 300 in accordance with one or more embodiments of the present disclosure. However, not all of these components may be required to practice one or more embodiments, and variations in the arrangement and type of the components may be made without departing from the spirit or scope of various embodiments of the present disclosure. In some embodiments, the client device 302a, client device 302b through client device 302n shown each at least includes a computer-readable medium, such as a random-access memory (RAM) 308 coupled to a processor 310 or FLASH memory. In some embodiments, the processor 310 may execute computer-executable program instructions stored in memory 308. In some embodiments, the processor 310 may include a microprocessor, an ASIC, and/or a state machine. In some embodiments, the processor 310 may include, or may be in communication with, media, for example computer-readable media, which stores instructions that, when executed by the processor 310, may cause the processor 310 to perform one or more steps described herein. In some embodiments, examples of computer-readable media may include, but are not limited to, an electronic, optical, magnetic, or other storage or transmission device capable of providing a processor, such as the processor 310 of client device 302a, with computer-readable instructions. In some embodiments, other examples of suitable media may include, but are not limited to, a floppy disk, CD-ROM, DVD, magnetic disk, memory chip, ROM, RAM, an ASIC, a configured processor, all optical media, all magnetic tape or other magnetic media, or any other medium from which a computer processor can read instructions. Also, various other forms of computer-readable media may transmit or carry instructions to a computer, including a router, private or public network, or other transmission device or channel, both wired and wireless. In some embodiments, the instructions may comprise code from any computer-programming language, including, for example, C, C++, Visual Basic, Java, Python, Perl, JavaScript, and etc.

In some embodiments, client devices 302a through 302n may also comprise a number of external or internal devices such as a mouse, a CD-ROM, DVD, a physical or virtual keyboard, a display, or other input or output devices. In some embodiments, examples of client devices 302a through 302n (e.g., clients) may be any type of processor-based platforms that are connected to a network 306 such as, without limitation, personal computers, digital assistants, personal digital assistants, smart phones, pagers, digital tablets, laptop computers, Internet appliances, and other processor-based devices. In some embodiments, client devices 302a through 302n may be specifically programmed with one or more application programs in accordance with one or more principles/methodologies detailed herein. In some embodiments, client devices 302a through 302n may operate on any operating system capable of supporting a browser or browser-enabled application, such as Microsoft™, Windows™, and/or Linux. In some embodiments, client devices 302a through 302n shown may include, for example, personal computers executing a browser application program such as Microsoft Corporation's Internet Explorer™, Apple Computer, Inc.'s Safari™, Mozilla Firefox, and/or Opera. In some embodiments, through the member computing client devices 302a through 302n, user 312a, user 312b through user 312n, may communicate over the exemplary network 306 with each other and/or with other systems and/or devices coupled to the network 306. As shown in FIG. 3, exemplary server devices 304 and 313 may include processor 305 and processor 314, respectively, as well as memory 317 and memory 316, respectively. In some embodiments, the server devices 304 and 313 may be also coupled to the network 306. In some embodiments, one or more client devices 302a through 302n may be mobile clients.

In some embodiments, at least one database of exemplary databases 307 and 315 may be any type of database, including a database managed by a database management system (DBMS). In some embodiments, an exemplary DBMS-managed database may be specifically programmed as an engine that controls organization, storage, management, and/or retrieval of data in the respective database. In some embodiments, the exemplary DBMS-managed database may be specifically programmed to provide the ability to query, backup and replicate, enforce rules, provide security, compute, perform change and access logging, and/or automate optimization. In some embodiments, the exemplary DBMS-managed database may be chosen from Oracle database, IBM DB2, Adaptive Server Enterprise, FileMaker, Microsoft Access, Microsoft SQL Server, MySQL, PostgreSQL, and a NoSQL implementation. In some embodiments, the exemplary DBMS-managed database may be specifically programmed to define each respective schema of each database in the exemplary DBMS, according to a particular database model of the present disclosure which may include a hierarchical model, network model, relational model, object model, or some other suitable organization that may result in one or more applicable data structures that may include fields, records, files, and/or objects. In some embodiments, the exemplary DBMS-managed database may be specifically programmed to include metadata about the data that is stored.

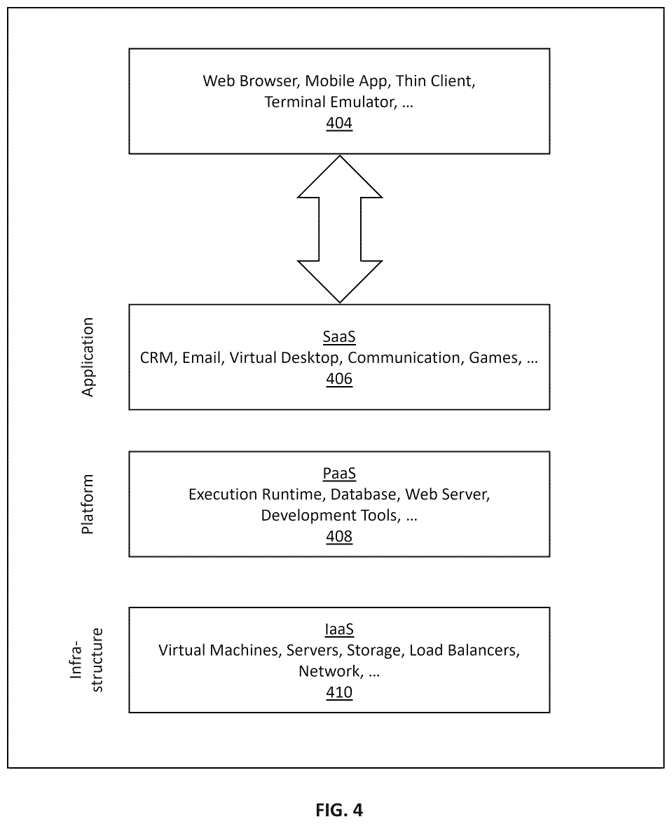

In some embodiments, the exemplary inventive computer-based systems/platforms, the exemplary inventive computer-based devices, and/or the exemplary inventive computer-based components of the present disclosure may be specifically configured to operate in a cloud computing/architecture 325 such as, but not limiting to: infrastructure a service (IaaS) 410, platform as a service (PaaS) 408, and/or software as a service (Saas) 406 using a web browser, mobile app, thin client, terminal emulator or other endpoint 404. FIG. 4 illustrates schematics of exemplary implementations of the cloud computing/architecture(s) in which the exemplary inventive computer-based systems/platforms, the exemplary inventive computer-based devices, and/or the exemplary inventive computer-based components of the present disclosure may be specifically configured to operate.

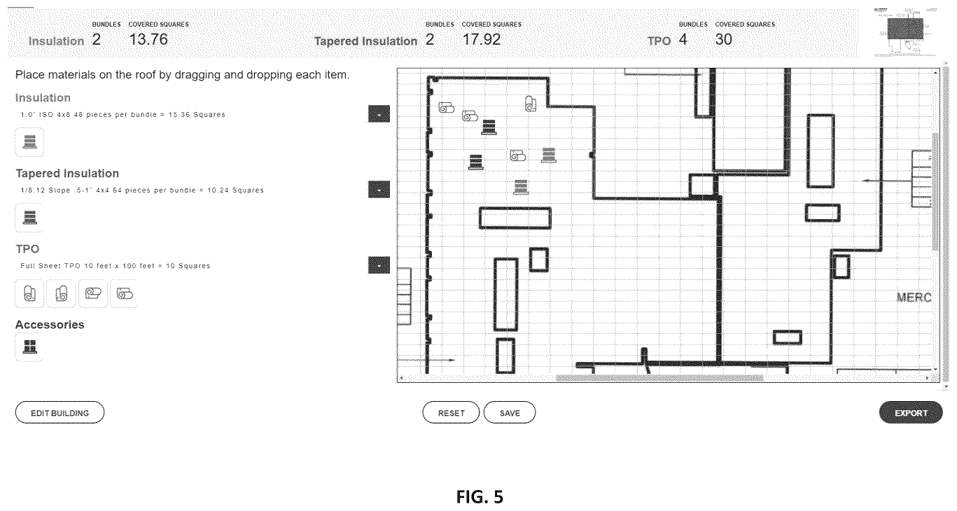

FIG. 5 illustrates an example GUI incorporating the roof design system 100 for generating a roof design and/or layout of roofing components.

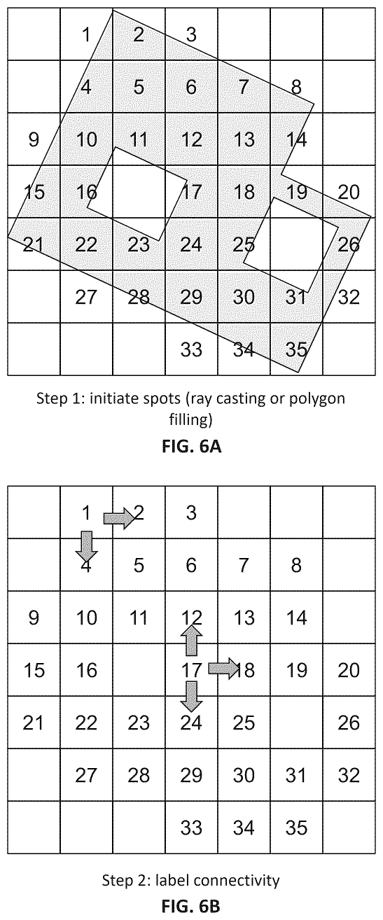

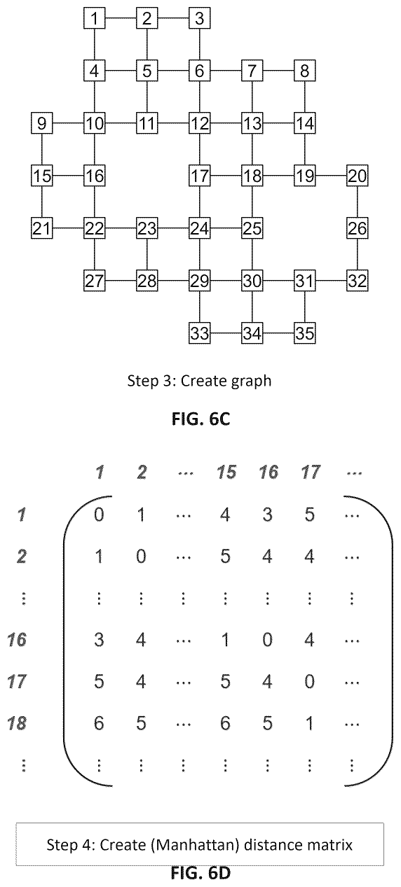

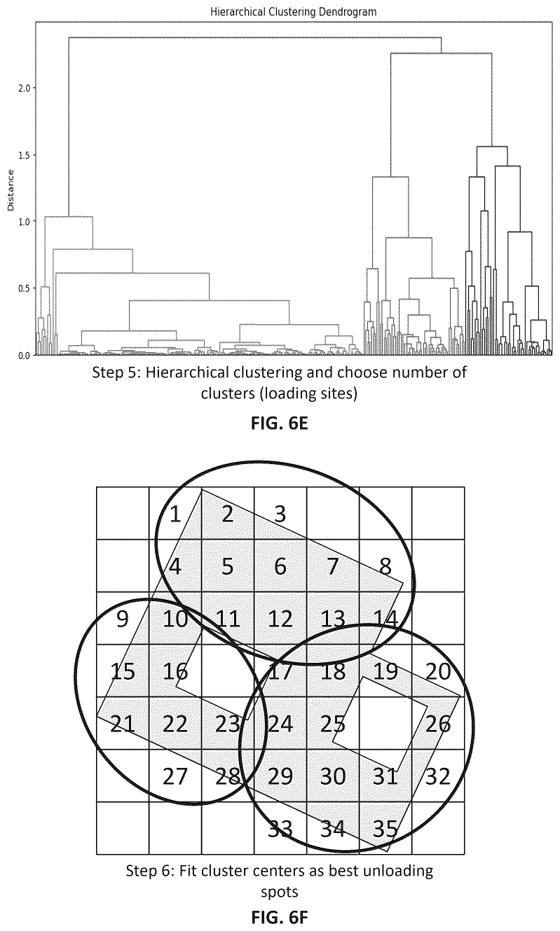

FIG. 6A through 6F illustrate steps in a flow for generating an optimal staging plan for a roof design in accordance with one or more embodiments detailed herein.

In some embodiments, a roof model may be processed identify optimal staging points on the roof where roof components can be distributed most efficient (e.g., by moving the components the least distance from a given staging point). Thus, the staging points may be identified, and the roof components assigned to each staging point.

In some embodiments, the roof may be mapped based on the roof model, e.g., by creating or otherwise overlaying a grid, set of coordinates, mesh, or other construct to represent two- or three-dimensional points in space across the roof, e.g., according to a predetermined pattern. For example, a grid having a predetermined grid size and/or grid spacing (e.g., spacing between the lines of the grid in length, width and/or height directions). To do so, an algorithm for generating spacing information for use in the construct of points across the roof may be applied to the roof model. For example, because the roof model may include a roof in a polygonal shape having x and y coordinates (e.g., in a Cartesian coordinate system), ray casting or polygon filling may be employed, or other graphical algorithm or any combination thereof. As a result, the roof model may be processed to develop a virtual mapped spaces for the roof on which mapped spots may be initiated (see, Step 1 in FIG. 6A). For example, the virtual mapped space may be a polygon representing the shape and construction of the roof sliced into minimum area units, such as units having a size of, e.g.: one six inch by six inch, foot by one foot, eighteen inch by eighteen inch, two foot by two foot, three foot by three foot.

In some embodiments, ray casting may be used to render a 3D roof model onto a 2D image plane. In ray casting, rays may be projected from a viewpoint on the roof model through each pixel on the image plane into the 3D scene to determine what objects these rays intersect. When a ray intersects an object in the scene, the algorithm calculates the color and brightness at that point. This information is then used to determine the color of the corresponding pixel in the final image to identify points along the roof in a two-dimensional space.

In some embodiments, polygon filling may be used to fill the interior of a polygon with a specific color or pattern, e.g., in the two-dimensional space associated with the roof. Polygon filling may include, e.g., scan-line filling that works by generating intersecting scan lines (horizontal lines) with the edges of the polygon, identifies the intersection points and sorts them by their x-coordinates to file the pixels between pairs of intersections on each scan line. Polygon filling may include, e.g., a flood fill algorithm where the algorithm starts from a seed point inside the polygon and spreads outwards, filling all connected pixels until it hits the boundary of the polygon, e.g., using either a 4-connected or 8-connected approach, depending on whether it fills pixels in four or eight directions. Polygon filling may include, e.g., a boundary fill algorithm that starts from a seed point and fills outward until it encounters the boundary color. Polygon filling may include, e.g., an edge table and/or active edge table algorithm that includes creating an edge table that lists all the edges of the polygon sorted by their y-coordinates. An active edge table is used to keep track of the edges that intersect the current scan line, where the active edge table is updated as it moves from one scan line to the next, filling the pixels between pairs of intersections.

In some embodiments, the mapped spots on the roof may be labelled, e.g., sequentially or by any other labelling methodology such that each spot has a unique identifier (see, Step 2 of FIG. 6B). Based on the labelled spots, an undirected connectivity graph may be created that includes fixed-size edges that connect each labelled spot (see, Step 3 of FIG. 6C). In some embodiments, connectivity graph may be a separate data structure separate from the virtual space. Thus, the mapping of spots may be represented based on relative connectivity to other spots via a custom data structure for the purpose without the memory or processing overhead of a virtual model or image.

In some embodiments, using the connectivity graph, a distance matrix may be calculated that tabulates the distances between pairs of objects or points according to one or more distance measures (see, Step 4 of FIG. 6D). In some embodiments, the distance measure(s) may include, without limitation, any one or more of Euclidean Distance (the straight-line distance between two points), Manhattan Distance (the sum of the absolute differences of their coordinates), Hamming Distance (the number of positions at which the corresponding elements are different), or other distance measure or any combination thereof.

In some embodiments, distance may include a spatial separation between two grid boxes, or may include other forms of distance. For example, the physical weight of the roof materials that need to be carried between the starting and the ending grid box may be factored into a distance. A measured or expected time, or physical work needed to traverse between two grid boxes, move an object or roof material, or to perform an installation of a particular roof material may be factored into the distance. In some embodiments, distance as used in the connectivity graph and/or distance matrix may be a weighted distance whereby the spatial separation is multiplied by the additional factor, such as the time to traverse, time to install, weight of the roof material, among other factors or any combination thereof. Thus, the distance mathematically represents more than spatial distance, but also factors affecting the ability to reach one spot from another spot

In some embodiments, the distance matrix may be a square matrix that has the same number of rows and columns where each element in the matrix represents the distance and/or weighted distance between two points, and where the diagonal elements may be zero, as they represent the distance from a point to itself.

In some embodiments, the distance matrix may be used to cluster spots using one or more clustering algorithms (see, Step 5 in FIG. 6E). The clustering algorithm may include, e.g., hierarchical cluster, k-Nearest Neighbor, k-means, Mean-Shift, Gaussian Mixture Model (GMM), agglomerative, density-based spatial clustering of applications with noise (DBSCAN), among others or any combination thereof. For example, hierarchical clustering may be employed to build a hierarchy of clusters either by merging smaller clusters into larger ones (agglomerative) or by splitting larger clusters into smaller ones (divisive), and thereby create a tree-like structure called a dendrogram. Indeed, hierarchical clustering may leverage the connectivity-based distance matrix because hierarchical clustering as a connectivity-based clustering technique. In some embodiments, the clustering criteria may include the sum of all distances to cluster centers.

In some embodiments, when a distance measurement is defined such as the travel distance, the physical work to move objects between distances, the time to travel or install objects between distances, or the time consumption to complete roof installation between two roof positions, the optimization of the staging may be a minimization of install time for the whole roof. Thus, the clustering criteria may be to minimize, for all clusters, such distance measurement from each grid box to the center of the cluster it is assigned to. Thus, the clusters may be dynamically defined to minimize the total measurement, and thereby minimize time of installation.

In some embodiments, the number of clusters may be determined based on, e.g., the size and shape of roof material to be installed, how many access points can be used to transport the roof material to the roof, among other factors. The number of clusters may be determined automatically based on such factors, or may be manually defined, or a combination thereof.

In some embodiments, the cluster centers may be identified as the optimal staging spots on the roof (see, Step 6 in FIG. 6F). The points on the roof that optimize distribution of roof components to minimize travel distance and/or time may be identified. In some embodiments, the amount of material unloaded to each spot may be determined by a sum of all spots in that cluster, where the sum may be of the distances from each spot to the cluster center based on the distance measurement(s) including the weighting factors detailed above. As a result, the staging spots and the amount of materials to be routed to each staging spot may be determined and output, e.g., as detailed above.

It is understood that at least one aspect/functionality of various embodiments described herein can be performed in real-time and/or dynamically. As used herein, the term “real-time” is directed to an event/action that can occur instantaneously or almost instantaneously in time when another event/action has occurred. For example, the “real-time processing,” “real-time computation,” and “real-time execution” all pertain to the performance of a computation during the actual time that the related physical process (e.g., a user interacting with an application on a mobile device) occurs, in order that results of the computation can be used in guiding the physical process.

As used herein, the term “dynamically” and term “automatically,” and their logical and/or linguistic relatives and/or derivatives, mean that certain events and/or actions can be triggered and/or occur without any human intervention. In some embodiments, events and/or actions in accordance with the present disclosure can be in real-time and/or based on a predetermined periodicity of at least one of: nanosecond, several nanoseconds, millisecond, several milliseconds, second, several seconds, minute, several minutes, hourly, several hours, daily, several days, weekly, monthly, etc.

In some embodiments, exemplary inventive, specially programmed computing systems and platforms with associated devices are configured to operate in the distributed network environment, communicating with one another over one or more suitable data communication networks (e.g., the Internet, satellite, etc.) and utilizing one or more suitable data communication protocols/modes such as, without limitation, IPX/SPX, X.25, AX.25, AppleTalk™, TCP/IP (e.g., HTTP), near-field wireless communication (NFC), RFID, Narrow Band Internet of Things (NBIOT), 3G, 4G, 5G, GSM, GPRS, WiFi, WiMax, CDMA, satellite, ZigBee, and other suitable communication modes.

The material disclosed herein may be implemented in software or firmware or a combination of them or as instructions stored on a machine-readable medium, which may be read and executed by one or more processors. A machine-readable medium may include any medium and/or mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that make the logic or processor. Of note, various embodiments described herein may, of course, be implemented using any appropriate hardware and/or computing software languages (e.g., C++, Objective-C, Swift, Java, JavaScript, Python, Perl, QT, etc.).

In some embodiments, one or more of illustrative computer-based systems or platforms of the present disclosure may include or be incorporated, partially or entirely into at least one personal computer (PC), laptop computer, ultra-laptop computer, tablet, touch pad, portable computer, handheld computer, palmtop computer, personal digital assistant (PDA), cellular telephone, combination cellular telephone/PDA, television, smart device (e.g., smart phone, smart tablet or smart television), mobile internet device (MID), messaging device, data communication device, and so forth.

In some embodiments, as detailed herein, one or more of the computer-based systems of the present disclosure may obtain, manipulate, transfer, store, transform, generate, and/or output any digital object and/or data unit (e.g., from inside and/or outside of a particular application) that can be in any suitable form such as, without limitation, a file, a contact, a task, an email, a message, a map, an entire application (e.g., a calculator), data points, and other suitable data. In some embodiments, as detailed herein, one or more of the computer-based systems of the present disclosure may be implemented across one or more of various computer platforms such as, but not limited to: (1) FreeBSD, NetBSD, OpenBSD; (2) Linux; (3) Microsoft Windows™; (4) Open VMS™; (5) OS X (MacOS™); (6) UNIX™; (7) Android; (8) iOS™; (9) Embedded Linux; (10) Tizen™; (11) WebOS™; (12) Adobe AIR™; (13) Binary Runtime Environment for Wireless (BREW™); (14) Cocoa™ (API); (15) Cocoa™ Touch; (16) Java™ Platforms; (17) JavaFX™; (18) QNX™; (19) Mono; (20) Google Blink; (21) Apple WebKit; (22) Mozilla Gecko™; (23) Mozilla XUL; (24).NET Framework; (25) Silverlight™; (26) Open Web Platform; (27) Oracle Database; (28) Qt™; (29) SAP NetWeaver™; (30) Smartface™; (31) Vexi™; (32) Kubernetes™ and (33) Windows Runtime (WinRT™) or other suitable computer platforms or any combination thereof. In some embodiments, illustrative computer-based systems or platforms of the present disclosure may be configured to utilize hardwired circuitry that may be used in place of or in combination with software instructions to implement features consistent with principles of the disclosure. Thus, implementations consistent with principles of the disclosure are not limited to any specific combination of hardware circuitry and software. For example, various embodiments may be embodied in many different ways as a software component such as, without limitation, a stand-alone software package, a combination of software packages, or it may be a software package incorporated as a “tool” in a larger software product.

For example, exemplary software specifically programmed in accordance with one or more principles of the present disclosure may be downloadable from a network, for example, a website, as a stand-alone product or as an add-in package for installation in an existing software application. For example, exemplary software specifically programmed in accordance with one or more principles of the present disclosure may also be available as a client-server software application, or as a web-enabled software application. For example, exemplary software specifically programmed in accordance with one or more principles of the present disclosure may also be embodied as a software package installed on a hardware device.

In some embodiments, illustrative computer-based systems or platforms of the present disclosure may be configured to handle numerous concurrent users that may be, but is not limited to, at least 100 (e.g., but not limited to, 100-999), at least 1,000 (e.g., but not limited to, 1,000-9,999), at least 10,000 (e.g., but not limited to, 10,000-99,999), at least 100,000 (e.g., but not limited to, 100,000-999,999), at least 1,000,000 (e.g., but not limited to, 1,000,000-9,999,999), at least 10,000,000 (e.g., but not limited to, 10,000,000-99,999,999), at least 100,000,000 (e.g., but not limited to, 100,000,000-999,999,999), at least 1,000,000,000 (e.g., but not limited to, 1,000,000,000-999,999,999,999), and so on.

In some embodiments, illustrative computer-based systems or platforms of the present disclosure may be configured to output to distinct, specifically programmed graphical user interface implementations of the present disclosure (e.g., a desktop, a web app., etc.). In various implementations of the present disclosure, a final output may be displayed on a displaying screen which may be, without limitation, a screen of a computer, a screen of a mobile device, or the like. In various implementations, the display may be a holographic display. In various implementations, the display may be a transparent surface that may receive a visual projection. Such projections may convey various forms of information, images, or objects. For example, such projections may be a visual overlay for a mobile augmented reality (MAR) application.

As used herein, term “server” should be understood to refer to a service point which provides processing, database, and communication facilities. By way of example, and not limitation, the term “server” can refer to a single, physical processor with associated communications and data storage and database facilities, or it can refer to a networked or clustered complex of processors and associated network and storage devices, as well as operating software and one or more database systems and application software that support the services provided by the server. Cloud servers are examples.

As used herein, terms “cloud,” “Internet cloud,” “cloud computing,” “cloud architecture,” and similar terms correspond to at least one of the following: (1) a large number of computers connected through a real-time communication network (e.g., Internet); (2) providing the ability to run a program or application on many connected computers (e.g., physical machines, virtual machines (VMs)) at the same time; (3) network-based services, which appear to be provided by real server hardware, and are in fact served up by virtual hardware (e.g., virtual servers), simulated by software running on one or more real machines (e.g., allowing to be moved around and scaled up (or down) on the fly without affecting the end user).

In some embodiments, the illustrative computer-based systems or platforms of the present disclosure may be configured to securely store and/or transmit data by utilizing one or more of encryption techniques (e.g., private/public key pair, Triple Data Encryption Standard (3DES), block cipher algorithms (e.g., IDEA, RC2, RC5, CAST and Skipjack), cryptographic hash algorithms (e.g., MD5, RIPEMD-160, RTRO, SHA-1, SHA-2, Tiger (TTH), WHIRLPOOL, RNGs).

Various detailed embodiments of the present disclosure, taken in conjunction with the accompanying FIGS., are disclosed herein; however, it is to be understood that the disclosed embodiments are merely illustrative. In addition, each of the examples given in connection with the various embodiments of the present disclosure is intended to be illustrative, and not restrictive.

Throughout the specification, the following terms take the meanings explicitly associated herein, unless the context clearly dictates otherwise. The phrases “in one embodiment” and “in some embodiments” as used herein do not necessarily refer to the same embodiment(s), though it may. Furthermore, the phrases “in another embodiment” and “in some other embodiments” as used herein do not necessarily refer to a different embodiment, although it may. Thus, as described below, various embodiments may be readily combined, without departing from the scope or spirit of the present disclosure.

In addition, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the terms “and” and “or” may be used interchangeably to refer to a set of items in both the conjunctive and disjunctive in order to encompass the full description of combinations and alternatives of the items. By way of example, a set of items may be listed with the disjunctive “or”, or with the conjunction “and.” In either case, the set is to be interpreted as meaning each of the items singularly as alternatives, as well as any combination of the listed items.

As used herein, the term “user” means at least one user. In some embodiments, the terms “user”, “subscriber” “consumer” or “customer” should be understood to refer to a user of an application or applications as described herein and/or a consumer of data supplied by a data provider. By way of example, and not limitation, the terms “user” or “subscriber” can refer to a person who receives data provided by the data or service provider over the Internet in a browser session, or can refer to an automated software application which receives the data and stores or processes the data.

The aforementioned examples are, of course, illustrative and not restrictive.

At least some aspects of the present disclosure will now be described with reference to the following numbered clauses.
Clause 1. A method comprising: receiving, via a roof computer aided design (CAD) tool, by at least one processor, an upload of a roof model representing a design of a roof; receiving, via the roof CAD tool, by the at least one processor, at least one user selection of at least one roofing component; wherein the at least one user selection comprises at least one portion of the roof model at which the at least one roofing component is to be positioned; wherein at least one roofing component comprises at least one dimension; generating, via the roof CAD tool, by the at least one processor, at least one roofing component overlay on the roof model; wherein the at least one roofing component overlay covers, based at least in part on the at least one dimension, at least one covered portion of the roof model corresponding to the at least one portion at which the at least one roofing component is to be positioned; receiving, via at least one staging plug-in to the roof CAD tool, by the at least one processor, the at least one roofing component overlay, the at least one roofing component and roof model; generating, from the uploaded at least one roofing component overlay, at least one roof staging plan comprising a plurality of actions and an order of the plurality of actions to install the at least one roofing component on the roof; and communicating, by at least one staging plug-in, the at least one roof staging plan to at least one distribution system, the at least one roof staging plan being configured to cause the at least one distribution system to initiate the plurality of actions according to the order of the plurality of actions.
Clause 2. The method of clause 1, wherein the design of the roof comprises at least one of: at least one roof feature, or at least one non-roof feature.
Clause 3. The method of clause 2, wherein the at least one roof feature comprises at least one structure on the roof.
Clause 4. The method of clause 2, wherein the at least one non-roof feature comprises at least one structure in proximity with the roof.
Clause 5. The method of clause 1, further comprising: utilizing, by the at least one processor, at least one staging layout machine learning model to output the at least one roof staging plan based at least in part on the roof model and the at least one roofing component.
Clause 6. The method of clause 1, further comprising: generating, by the at least one processor, in response to at least one user selection, the at least one roof staging plan.
Clause 7. The method of clause 1, further comprising: providing, via the at least one staging plug-in to the roof CAD tool, a selectable set of roofing components; and enabling, via the at least one staging plug-in to the roof CAD tool, the user to perform the at least one user selection of the at least one roofing component from among the selectable set of roofing components.
Clause 8. The method of clause 1, wherein the at least one roof staging plan comprises a plurality of unique roofing component parts associated with the at least one roofing component.
Clause 9. The method of clause 8, further comprising: tracking, by the at least one processor, a condition of each unique roofing component part based at least in part on a unique roofing component part identifier associated with each unique roofing component part.
Clause 10. The method of clause 1, wherein the at least one roof staging plan comprises at least one dimension alteration to the at least one roofing component based at least in part on the roof model and the at least one dimension of the at least one roofing component.
Clause 11. A system comprising: at least one processor in communication with at least one non-transitory computer readable medium having software instructions stored thereon, wherein the at least one processor, upon execution of the software instructions, is configured to perform a method comprising: receiving, via a roof computer aided design (CAD) tool, by at least one processor, an upload of a roof model representing a design of a roof; receiving, via the roof CAD tool, by the at least one processor, at least one user selection of at least one roofing component; wherein the at least one user selection comprises at least one portion of the roof model at which the at least one roofing component is to be positioned; wherein at least one roofing component comprises at least one dimension; generating, via the roof CAD tool, by the at least one processor, at least one roofing component overlay on the roof model; wherein the at least one roofing component overlay covers, based at least in part on the at least one dimension, at least one covered portion of the roof model corresponding to the at least one portion at which the at least one roofing component is to be positioned; receiving, via at least one staging plug-in to the roof CAD tool, by the at least one processor, the at least one roofing component overlay, the at least one roofing component and roof model; generating, from the uploaded at least one roofing component overlay, at least one roof staging plan comprising a plurality of actions and an order of the plurality of actions to install the at least one roofing component on the roof; and communicating, by at least one staging plug-in, the at least one roof staging plan to at least one distribution system, the at least one roof staging plan being configured to cause the at least one distribution system to initiate the plurality of actions according to the order of the plurality of actions.
Clause 12. The system of clause 11, wherein the design of the roof comprises at least one of: at least one roof feature, or at least one non-roof feature.
Clause 13. The system of clause 12, wherein the at least one roof feature comprises at least one structure on the roof.
Clause 14. The system of clause 12, wherein the at least one non-roof feature comprises at least one structure in proximity with the roof.
Clause 15. The system of clause 11, wherein the method further comprises: utilizing at least one staging layout machine learning model to output the at least one roof staging plan based at least in part on the roof model and the at least one roofing component.
Clause 16. The system of clause 11, wherein the method further comprises: generating, in response to at least one user selection, the at least one roof staging plan.
Clause 17. The system of clause 11, wherein the method further comprises: providing, via the at least one staging plug-in to the roof CAD tool, a selectable set of roofing components; and enabling, via the at least one staging plug-in to the roof CAD tool, the user to perform the at least one user selection of the at least one roofing component from among the selectable set of roofing components.
Clause 18. The system of clause 11, wherein the at least one roof staging plan comprises a plurality of unique roofing component parts associated with the at least one roofing component.
Clause 19. The system of clause 18, wherein the method further comprises: tracking, by the at least one processor, a condition of each unique roofing component part based at least in part on a unique roofing component part identifier associated with each unique roofing component part.
Clause 20. The system of clause 11, wherein the at least one roof staging plan comprises at least one dimension alteration to the at least one roofing component based at least in part on the roof model and the at least one dimension of the at least one roofing component.

Publications cited throughout this document are hereby incorporated by reference in their entirety. While one or more embodiments of the present disclosure have been described, it is understood that these embodiments are illustrative only, and not restrictive, and that many modifications may become apparent to those of ordinary skill in the art, including that various embodiments of the inventive methodologies, the illustrative systems and platforms, and the illustrative devices described herein can be utilized in any combination with each other. Further still, the various steps may be carried out in any desired order (and any desired steps may be added and/or any desired steps may be eliminated).

What is claimed is:

1. A method comprising:
receiving, via a roof computer aided design (CAD) tool, by at least one processor, an upload of a roof model representing a design of a roof;
receiving, via the roof CAD tool, by the at least one processor, at least one user selection of at least one roofing component;
wherein the at least one user selection comprises at least one portion of the roof model at which the at least one roofing component is to be positioned;
wherein at least one roofing component comprises at least one dimension;
generating, via the roof CAD tool, by the at least one processor, at least one roofing component overlay on the roof model;
wherein the at least one roofing component overlay covers, based at least in part on the at least one dimension, at least one covered portion of the roof model corresponding to the at least one portion at which the at least one roofing component is to be positioned;
receiving, via at least one staging plug-in to the roof CAD tool, by the at least one processor, the at least one roofing component overlay, the at least one roofing component and roof model;
generating, from the uploaded at least one roofing component overlay, at least one roof staging plan comprising a plurality of actions and an order of the plurality of actions to install the at least one roofing component on the roof; and
communicating, by at least one staging plug-in, the at least one roof staging plan to at least one distribution system, the at least one roof staging plan being configured to cause the at least one distribution system to initiate the plurality of actions according to the order of the plurality of actions.

2. The method of claim 1, wherein the design of the roof comprises at least one of:
at least one roof feature, or
at least one non-roof feature.

3. The method of claim 2, wherein the at least one roof feature comprises at least one structure on the roof.

4. The method of claim 2, wherein the at least one non-roof feature comprises at least one structure in proximity with the roof.

5. The method of claim 1, further comprising:
utilizing, by the at least one processor, at least one staging layout machine learning model to output the at least one roof staging plan based at least in part on the roof model and the at least one roofing component.

6. The method of claim 1, further comprising:
generating, by the at least one processor, in response to at least one user selection, the at least one roof staging plan.

7. The method of claim 1, further comprising:
providing, via the at least one staging plug-in to the roof CAD tool, a selectable set of roofing components; and
enabling, via the at least one staging plug-in to the roof CAD tool, the user to perform the at least one user selection of the at least one roofing component from among the selectable set of roofing components.

8. The method of claim 1, wherein the at least one roof staging plan comprises a plurality of unique roofing component parts associated with the at least one roofing component.

9. The method of claim 8, further comprising:
tracking, by the at least one processor, a condition of each unique roofing component part based at least in part on a unique roofing component part identifier associated with each unique roofing component part.

10. The method of claim 1, wherein the at least one roof staging plan comprises at least one dimension alteration to the at least one roofing component based at least in part on the roof model and the at least one dimension of the at least one roofing component.

11. A system comprising:
at least one processor in communication with at least one non-transitory computer readable medium having software instructions stored thereon, wherein the at least one processor, upon execution of the software instructions, is configured to perform a method comprising:
receiving, via a roof computer aided design (CAD) tool, by at least one processor, an upload of a roof model representing a design of a roof;
receiving, via the roof CAD tool, by the at least one processor, at least one user selection of at least one roofing component;
wherein the at least one user selection comprises at least one portion of the roof model at which the at least one roofing component is to be positioned;
wherein at least one roofing component comprises at least one dimension;
generating, via the roof CAD tool, by the at least one processor, at least one roofing component overlay on the roof model;
wherein the at least one roofing component overlay covers, based at least in part on the at least one dimension, at least one covered portion of the roof model corresponding to the at least one portion at which the at least one roofing component is to be positioned;
receiving, via at least one staging plug-in to the roof CAD tool, by the at least one processor, the at least one roofing component overlay, the at least one roofing component and roof model;
generating, from the uploaded at least one roofing component overlay, at least one roof staging plan comprising a plurality of actions and an order of the plurality of actions to install the at least one roofing component on the roof; and
communicating, by at least one staging plug-in, the at least one roof staging plan to at least one distribution system, the at least one roof staging plan being configured to cause the at least one distribution system to initiate the plurality of actions according to the order of the plurality of actions.

12. The system of claim 11, wherein the design of the roof comprises at least one of:
at least one roof feature, or
at least one non-roof feature.

13. The system of claim 12, wherein the at least one roof feature comprises at least one structure on the roof.

14. The system of claim 12, wherein the at least one non-roof feature comprises at least one structure in proximity with the roof.

15. The system of claim 11, wherein the method further comprises:
utilizing at least one staging layout machine learning model to output the at least one roof staging plan based at least in part on the roof model and the at least one roofing component.

16. The system of claim 11, wherein the method further comprises:
generating, in response to at least one user selection, the at least one roof staging plan.

17. The system of claim 11, wherein the method further comprises:
providing, via the at least one staging plug-in to the roof CAD tool, a selectable set of roofing components; and
enabling, via the at least one staging plug-in to the roof CAD tool, the user to perform the at least one user selection of the at least one roofing component from among the selectable set of roofing components.

18. The system of claim 11, wherein the at least one roof staging plan comprises a plurality of unique roofing component parts associated with the at least one roofing component.

19. The system of claim 18, wherein the method further comprises:
tracking, by the at least one processor, a condition of each unique roofing component part based at least in part on a unique roofing component part identifier associated with each unique roofing component part.

20. The system of claim 11, wherein the at least one roof staging plan comprises at least one dimension alteration to the at least one roofing component based at least in part on the roof model and the at least one dimension of the at least one roofing component.
